(19) United States
(12) Patent Application Publication
(10) Pub. No.: US 2024/0274644 A1
(43) Pub. Date: Aug. 15, 2024

(54) DISPLAY DEVICE AND METHOD FOR MANUFACTURING THE SAME

(71) Applicant: Samsung Display Co., LTD., Yongin-si (KR)

(72) Inventor: Tae Gyun KIM, Yongin-si (KR)

(21) Appl. No.: 18/426,236

(22) Filed: Jan. 29, 2024

(30) Foreign Application Priority Data
Feb. 10, 2023 (KR) 10-2023-0017971

(51) Int. Cl. H01L 27/15; G09G 3/3208; H01L 33/50; H01L 33/60

(52) U.S. Cl. CPC H01L 27/156; G09G 3/3208; H01L 33/50; H01L 33/60; G09G 2300/0408; G09G 2300/0413; H01L 2933/0041; H01L 2933/0058

(57) ABSTRACT

The present disclosure may provide display device and a method for manufacturing the same. The display device includes a substrate including pixel circuit units, a plurality of pixel electrodes on the pixel circuit units of the substrate and including first connection electrodes thereon and a plurality of light emitting elements on the pixel electrodes and including second connection electrodes bonded to the first connection electrodes, wherein each of the second connection electrodes includes a plurality of sub-connection electrodes that are spaced from each other.

### CROSS-REFERENCE TO RELATED APPLICATION

This application claims priority to and the benefit of Korean Patent Application No. 10-2023-0017971, filed on Feb. 10, 2023, in the Korean Intellectual Property Office, the entire content of which is incorporated by reference herein.

### BACKGROUND

### 1. Field

The present disclosure relates to a display device and a method for manufacturing the same.

### 2. Description of the Related Art

The importance of display devices has increased with the development of multimedia. Accordingly, various types of display devices such as organic light emitting diode (OLED) displays and liquid crystal displays (LCDs) have been used.

The display devices are devices for displaying images, and include display panels such as organic light emitting display panels or liquid crystal display panels. Among them, the light emitting display panel may include light emitting elements such as light emitting diodes (LEDs), and examples of such light emitting diodes include organic light emitting diodes (OLEDs) that use an organic material as a light emitting material, inorganic light emitting diodes that use an inorganic material as a light emitting material, and the like.

### SUMMARY

Aspects of embodiments of the present disclosure provide a display device in which there is no need to align first connection electrodes of a light emitting element layer and second connection electrodes of pixel circuit units with each other, and a method for manufacturing the same.

The aspects and features of embodiments of the present disclosure are not limited to those mentioned above, and additional aspects and features of the present disclosure, which are not mentioned herein, will be clearly understood by those skilled in the art from the following description of the present disclosure.

According to one or more embodiments, a display device includes a substrate including pixel circuit units, a plurality of pixel electrodes and first connection electrodes located thereon, the plurality of pixel electrodes being on the pixel circuit units of the substrate, and a plurality of light emitting elements on the plurality of pixel electrodes and including second connection electrodes bonded to the first connection electrodes, wherein each of the second connection electrodes includes a plurality of sub-connection electrodes that are spaced from each other.

The display device further includes a first insulating layer on the substrate at locations wherein the first connection electrodes are not located, and a plurality of dummy electrodes on the first insulating layer and not overlapping the first connection electrode.

The display device further includes a second insulating layer between the plurality of dummy electrodes.

Wherein at least one of the plurality of sub-connection electrodes protrudes outside the first connection electrode, and the at least one sub-connection electrode protruding outside the first connection electrode from among the plurality of sub-connection electrodes is on the first insulating layer.

The display device further includes a third insulating layer on upper surfaces and side surfaces of the plurality of light emitting elements, upper surfaces of the plurality of dummy electrodes, and an upper surface of the second insulating layer, wherein the third insulating layer includes openings on upper surface of the plurality of light emitting elements.

Wherein the plurality of sub-connection electrodes and the plurality of dummy electrodes are spaced from each other by a first interval in at least a first direction, and the dummy electrode neighboring to the sub-connection electrode is spaced from the sub-connection electrode by the first distance in at least the first direction.

Wherein each of the plurality of sub-connection electrodes has a first width in a first direction, the first connection electrode has a second width in the first direction, and the first width is smaller than the second width.

Wherein a sum of the first widths of the plurality of sub-connection electrodes arranged in the first direction in the second connection electrode is smaller than the second width of the first connection electrode.

The display device further includes a common electrode on the third insulating layer and electrically connected to the plurality light emitting elements through the openings.

The display device further includes partition walls between the plurality of light emitting elements, the partition walls defining spaces in emission areas on the respective light emitting elements, wavelength conversion layers located in the spaces, a first reflective layer on side surfaces of the plurality of light emitting elements, and a second reflective layer on side surfaces of the wavelength conversion layers.

Wherein a length of the wavelength conversion layer in a direction perpendicular to a thickness direction of the substrate is greater than a length of the light emitting element in the direction perpendicular to the thickness direction of the substrate, and the display device further includes a third reflective layer at bottom portions of the wavelength conversion layers that do not overlap the light emitting elements.

The display device further includes light blocking members on the partition walls, and color filters on the wavelength conversion layers.

According to one or more embodiments, a method for manufacturing a display device includes forming first connection electrodes and a first insulating layer on pixel electrodes formed on pixel circuit units of a first substrate, forming a plurality of connection electrode patterns and a second insulating layer over an entire surface of a light emitting material layer of a second substrate, bonding the first connection electrodes and the connection electrode patterns to each other and separating the second substrate and forming light emitting elements by etching the light emitting material layer, wherein the plurality of connection electrode patterns include a plurality of sub-connection electrodes bonded to the first connection electrode and a plurality of dummy electrodes that do not overlap the first connection electrode.

Wherein the plurality of sub-connection electrodes bonded to the first connection electrode are defined as second connection electrodes and connect the light emitting element and the pixel electrode to each other.

Wherein the plurality of connection electrode patterns are spaced from each other by a first distance in at least a first direction.

Wherein each of the plurality of sub-connection electrodes has a first width in a first direction, the first connection electrode has a second width in the first direction, and the first width is smaller than the second width.

The method for manufacturing a display device further includes after the forming of the light emitting elements, forming a third insulating layer on upper surfaces and side surfaces of the light emitting elements, upper surfaces of the plurality of dummy electrodes, and an upper surface of the second insulating layer, forming openings exposing portions of the upper surfaces of the light emitting elements by etching the third insulating layer on the upper surfaces of the light emitting elements and forming a common electrode on the openings and the third insulating layer.

The method for manufacturing a display device further includes removing a reflective layer in a first direction and a second direction by an etching material and forming a first reflective layer overlapping the side surfaces of the light emitting elements by depositing the reflective layer on the common electrode and then forming a large voltage difference in a third direction.

The method for manufacturing a display device further includes forming spaces for wavelength conversion layers and partition walls by applying an organic insulating material layer to the light emitting elements so as to cover the light emitting elements and etching the organic insulating material layer on the light emitting elements and forming the wavelength conversion layers in the spaces.

The method for manufacturing a display device further includes before the forming of the wavelength conversion layers, removing a reflective layer in the first direction and the second direction by an etching material and forming a second reflective layer overlapping side surfaces of the spaces by depositing the reflective layer on the partition walls and the spaces and then forming a large voltage difference in the third direction.

With a display device and a method for manufacturing the same according to embodiments, there is no need to align first connection electrodes of a light emitting element layer and second connection electrodes of pixel circuit units with each other.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a layout diagram illustrating a display device according to one or more embodiments;

FIG. 2 is a layout diagram illustrating an area A of FIG. 1 in detail;

FIG. 3 is a layout diagram illustrating pixels of a display panel according to one or more embodiments;

FIG. 4 is a cross-sectional view illustrating an example of the display panel taken along the line A-A′ of FIG. 2;

FIG. 5 is a cross-sectional view illustrating an example of the display panel taken along the line B-B′ of FIG. 3;

FIG. 6 is an enlarged cross-sectional view illustrating a light emitting element of a second emission area of FIG. 5;

FIG. 7 is a layout diagram illustrating pixels of the display panel including a first connection electrode and a second connection electrode of FIG. 6;

FIG. 8 is an enlarged cross-sectional view illustrating an example of a light emitting element of FIG. 5 in detail;

FIG. 9 is a cross-sectional view illustrating an example of the display panel taken along the line B-B′ of FIG. 3;

FIG. 10 is an enlarged cross-sectional view illustrating a light emitting element of a second emission area of FIG. 9;

FIG. 11 is a layout diagram illustrating pixels of the display panel including a first connection electrode and a second connection electrode of FIG. 10;

FIG. 12 is a cross-sectional view illustrating an example of the display panel taken along the line B-B′ of FIG. 3;

FIG. 13 is a cross-sectional view illustrating an example of the display panel taken along the line B-B′ of FIG. 3;

FIG. 14 is a cross-sectional view illustrating an example of the display panel taken along the line B-B′ of FIG. 3;

FIG. 15 is a flowchart illustrating a method for manufacturing a display device according to one or more embodiments.

FIGS. 16 to 33 are cross-sectional views for describing the method for manufacturing a display device according to one or more embodiments.

FIG. 34 is a view illustrating a virtual reality device including a display device according to one or more embodiments.

FIG. 35 is a view illustrating a smart device including a display device according to one or more embodiments.

FIG. 36 is a view illustrating a vehicle dashboard and a center fascia including a display device according to one or more embodiments.

FIG. 37 is a view illustrating a transparent display device including a display device according to one or more embodiments.

### DETAILED DESCRIPTION

Embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

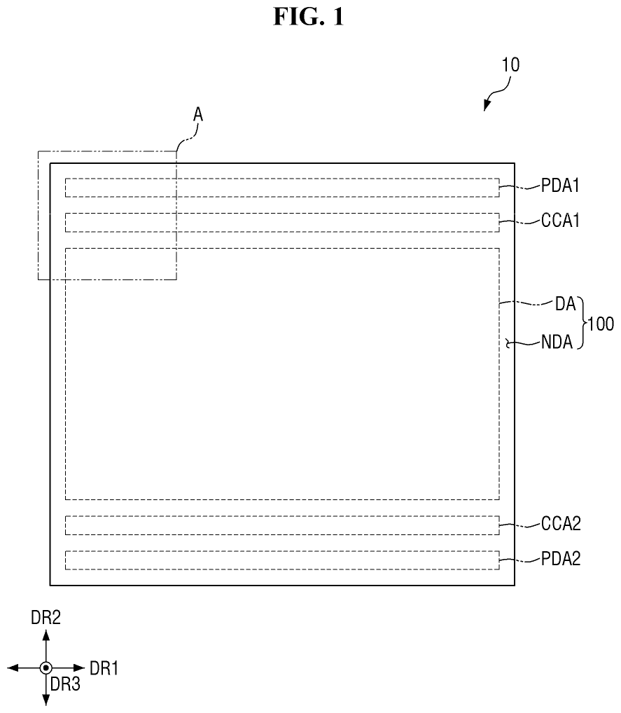

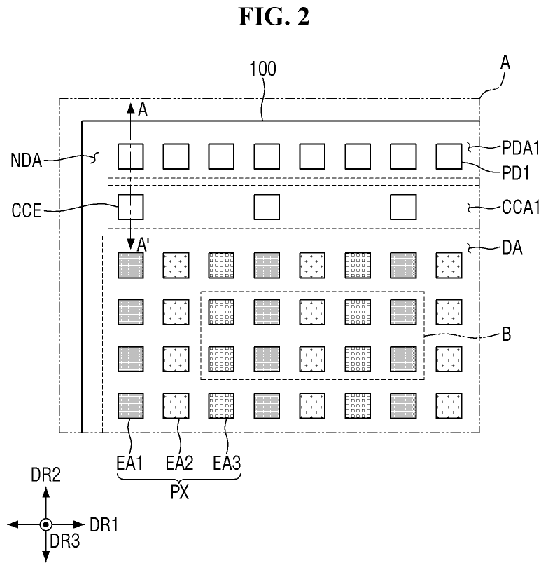

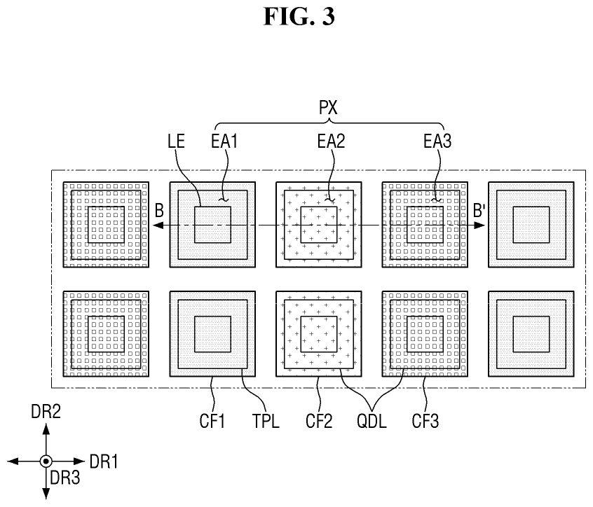

FIG. 1 is a layout diagram illustrating a display device according to one or more embodiments. FIG. 2 is a layout diagram illustrating an area A of FIG. 1 in more detail. FIG. 3 is a layout diagram illustrating pixels of a display panel according to one or more embodiments.

It will be mainly described in FIGS. 1 to 3 that a display device according to one or more embodiments is a micro or nano light emitting diode display device including micro or nano light emitting diodes as light emitting elements LE, the present disclosure is not limited thereto.

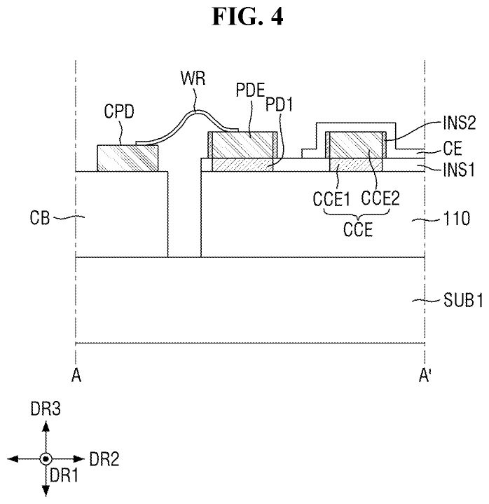

In addition, it will be mainly described in FIGS. 1 to 3 that the display device according to one or more embodiments is a light emitting diode on silicon (LEDoS) in which light emitting diodes are disposed as light emitting elements on a semiconductor circuit substrate 110 (e.g., see FIG. 4) formed by a semiconductor process using a silicon wafer, but it is to be noted that the present disclosure is not limited thereto.

In addition, in FIGS. 1 to 3, a first direction DR1 refers to a transverse direction of a display panel 100, a second direction DR2 refers to a longitudinal direction of the display panel 100, and a third direction DR3 refers to a thickness direction of the display panel 100 or a thickness direction of the semiconductor circuit substrate 110. In this case, “left”, “right”, “upper”, and “lower” refer to directions when the display panel 100 is viewed in a plan view. For example, “right side” refers to one side in the first direction DR1, “left side” refers to the other side in the first direction DR1, “upper side” refers to one side in the second direction DR2, and “lower side” refers to the other side in the second direction DR2. In addition, “upper portion” refers to one side in the third direction DR3, and “lower portion” refers to the other side in the third direction DR3.

Referring to FIGS. 1 to 3, a display device 10 according to one or more embodiments includes a display panel 100 including a display area DA and a non-display area NDA along an edge or periphery of the display area DA.

The display panel 100 may have a rectangular shape, in a plan view, having long sides in the first direction DR1 and short sides in the second direction DR2. However, the shape of the display panel 100 in a plan view is not limited thereto, and the display panel 100 may have polygonal shapes other than the rectangular shape, a circular shape, an elliptical shape, or an irregular shape in a plan view.

The display area DA may be an area in which an image is displayed, and the non-display area NDA may be an area in which no image is displayed. A shape of the display area DA in a plan view may follow the shape of the display panel 100 in a plan view. It has been illustrated in FIG. 1 that the shape of the display area DA in a plan view is a rectangular shape. The display area DA may be disposed in a central area of the display panel 100. The non-display area NDA may be disposed around the display area DA. The non-display area NDA may be disposed to surround the display area DA.

The display area DA of the display panel 100 may include a plurality of pixels PX. The pixel PX may be defined as a minimum light emitting unit capable of displaying white light.

Each of the plurality of pixels PX may include a plurality of emission areas EA1, EA2, and EA3 configured to emit light. It has been illustrated in an embodiment of the present disclosure that each of the plurality of pixels PX includes three emission areas EA1, EA2, and EA3, but the present disclosure is not limited thereto. For example, each of the plurality of pixels PX may include four emission areas. Each of the plurality of emission areas EA1, EA2, and EA3 may include a light emitting element LE emitting first light.

Each of the first emission areas EA1 refers to an area configured to emit the first light. Each of the first emission areas EA1 may output the first light output from the light emitting element LE as it is. The first light may be light of a blue wavelength band. The blue wavelength band may be approximately 370 nm to 460 nm, but the present disclosure is not limited thereto.

Each of the second emission areas EA2 refers to an area configured to emit second light. Each of the second emission areas EA2 may convert some of the first light output from the light emitting element LE into the second light and emit the second light. The second light may be light of a green wavelength band. The green wavelength band may be approximately 480 nm to 560 nm, but the present disclosure is not limited thereto.

Each of the third emission areas EA3 refers to an area configured to emit third light. Each of the third emission areas EA3 may convert some of the first light output from the light emitting element LE into the third light and emit the third light. The third light may be light of a red wavelength band. The red wavelength band may be approximately 600 nm to 750 nm, but the present disclosure is not limited thereto.

The first emission areas EA1, the second emission areas EA2, and the third emission areas EA3 may be alternately arranged along the first direction DR1. For example, the first emission areas EA1, the second emission areas EA2, and the third emission areas EA3 may be disposed in the order of the first emission area EA1, the second emission area EA2, and the third emission area EA3 along the first direction DR1.

The first emission areas EA1 may be arranged along the second direction DR2. The second emission areas EA2 may be arranged along the second direction DR2. The third emission areas EA3 may be arranged along the second direction DR2.

Each of the first emission areas EA1 may include a light emitting element LE, a light transmission layer TPL, and a first color filter CF1. The light emitting element LE, the light transmission layer TPL, and the first color filter CF1 may overlap each other in the third direction DR3. The light transmission layer TPL may transmit the first light output from the light emitting element LE therethrough as it is, and the first color filter CF1 may transmit the first light therethrough. Therefore, each of the first emission areas EA1 may emit the first light.

Each of the second emission areas EA2 may include a light emitting element LE, a wavelength conversion layer QDL, and a second color filter CF2. The light emitting element LE, the wavelength conversion layer QDL, and the second color filter CF2 may overlap each other in the third direction DR3. The wavelength conversion layer QDL may convert some of the first light output from the light emitting element LE into fourth light and emit the fourth light. For example, the fourth light may be light of a yellow wavelength band. The fourth light may be light including both a green wavelength band and a red wavelength band. That is, the fourth light may be a mixture of the second light and the third light. The second color filter CF2 may transmit the second light therethrough. Therefore, each of the second emission areas EA2 may emit the second light.

Each of the third emission areas EA3 may include a light emitting element LE, a wavelength conversion layer QDL, and a third color filter CF3. The light emitting element LE, the wavelength conversion layer QDL, and the third color filter CF3 may overlap each other in the third direction DR3. The wavelength conversion layer QDL may convert some of the first light output from the light emitting element LE into fourth light and emit the fourth light. The third color filter CF3 may transmit the third light therethrough. Therefore, each of the third emission areas EA3 may emit the third light.

Each of an area of the light transmission layer TPL and an area of the wavelength conversion layer QDL may be greater than an area of the light emitting element LE. An area of each of the first color filter CF1, the second color filter CF2, and the third color filter CF3 may be greater than the area of the light emitting element LE. In addition, the area of each of the first color filter CF1, the second color filter CF2, and the third color filter CF3 may be greater than each of the area of the light transmission layer TPL and the area of the wavelength conversion layer QDL.

In the first emission area EA1, the light emitting element LE may be completely covered by the light transmission layer TPL, and the light transmission layer TPL may be completely covered by the first color filter CF1. In addition, in the second emission area EA2, the light emitting element LE may be completely covered by the wavelength conversion layer QDL, and the wavelength conversion layer QDL may be completely covered by the second color filter CF2. Furthermore, in the third emission area EA3, the light emitting element LE may be completely covered by the wavelength conversion layer QDL, and the wavelength conversion layer QDL may be completely covered by the third color filter CF3.

It has been illustrated that a shape of the light transmission layer TPL in a plan view, a shape of the wavelength conversion layer QDL in a plan view, a shape of the first color filter CF1 in a plan view, a shape of the second color filter CF2 in a plan view, and a shape of third color filter CF3 in a plan view follow a shape of the light emitting element LE in a plan view. For example, when the light emitting element LE has a rectangular shape in a plan view, each of the light transmission layer TPL, the wavelength conversion layer QDL, the first color filter CF1, the second color filter CF2, and the third color filters CF3 may have a rectangular shape in a plan view. Alternatively, the light emitting element LE may have polygonal shapes other than a rectangular shape, a circular shape, an elliptical shape, or an irregular shape, and in this case, each of the light transmission layer TPL, the wavelength conversion layer QDL, the first color filter CF1, the second color filter CF2, and the third color filters CF3 may also have polygonal shapes other than a rectangular shape, a circular shape, an elliptical shape, or an irregular shape.

Alternatively, a shape of the light transmission layer TPL in a plan view, a shape of the wavelength conversion layer QDL in a plan view, a shape of the first color filter CF1 in a plan view, a shape of the second color filter CF2 in a plan view, and a shape of third color filter CF3 in a plan view may not follow a shape of the light emitting element LE in a plan view. In this case, each of the shape of the light transmission layer TPL in a plan view, the shape of the wavelength conversion layer QDL in a plan view, the shape of the first color filter CF1 in a plan view, the shape of the second color filter CF2 in a plan view, and the shape of third color filter CF3 in a plan view may be different from the shape of the light emitting element LE in a plan view. In addition, each of the shape of the light transmission layer TPL in a plan view and the shape of the wavelength conversion layer QDL in a plan view may be different from each of the shape of the first color filter CF1 in a plan view, the shape of the second color filter CF2 in a plan view, and the shape of third color filter CF3 in a plan view.

The non-display area NDA may include a first common connection area CCA1, a second common connection area CCA2, a first pad part PDA1, and a second pad part PDA2.

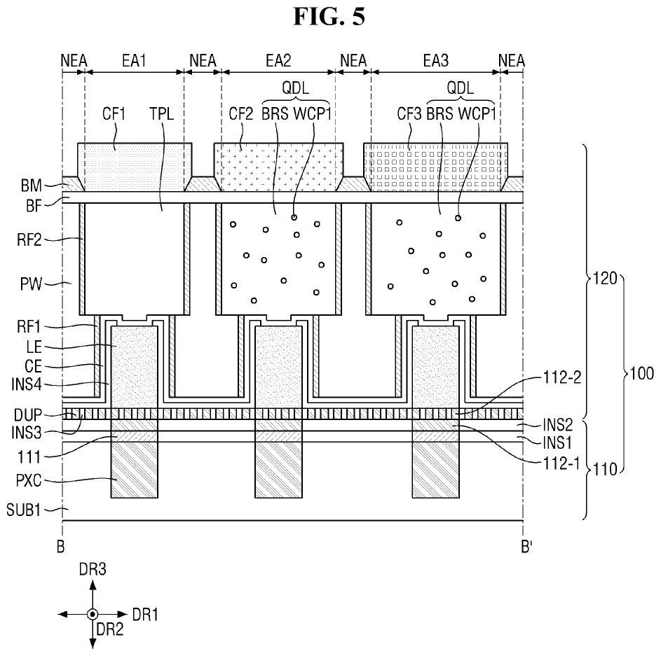

The first common connection area CCA1 may be disposed between the first pad part PDA1 and the display area DA. The second common connection area CCA2 may be disposed between the second pad part PDA2 and the display area DA. Each of the first common connection area CCA1 and the second common connection area CCA2 may include a plurality of common connection electrodes CCE connected to a common electrode CE (see FIGS. 4 and 5). Accordingly, a common voltage may be supplied to the common electrode CE (see FIGS. 4 and 5) through the plurality of common connection electrodes CCE. The plurality of common connection electrodes CCE of the first common connection area CCA1 may be electrically connected to any one of first pads PD1 of the first pad part PDA1.

The first pad part PDA1 may be disposed on the upper side of the display panel 100. The first pad part PDA1 may include first pads PD1 connected to an external circuit board CB (see FIG. 4).

The second pad part PDA2 may be disposed on the lower side of the display panel 100. The second pad part PDA2 may include second pads to be connected to the external circuit board CB (see FIG. 4). The second pad part PDA2 may be omitted.

FIG. 4 is a cross-sectional view illustrating an example of the display panel taken along the line A-A′ of FIG. 2.

The display panel 100 according to one or more embodiments may include a first substrate SUB1, a semiconductor circuit substrate 110 disposed on the first substrate SUB1, common connection electrodes CCE disposed on the semiconductor circuit substrate 110, a common electrode CE covering the common connection electrodes CCE, first pads PD1 disposed on the semiconductor circuit substrate 110, and pad connection electrodes PDE disposed on the first pads PD1.

The semiconductor circuit substrate 110 and the circuit board CB may be disposed on the first substrate SUB1. The semiconductor circuit substrate 110 and the circuit board CB may be attached to an upper surface of the first substrate SUB1 using an adhesive member such as a pressure sensitive adhesive.

The circuit board CB may be a flexible printed circuit board (FPCB), a printed circuit board (PCB), a flexible printed circuit (FPC), or a flexible film such as a chip on film (COF).

The first pad PD1 may be connected to the common connection electrode CCE through a wiring of the semiconductor circuit substrate 110.

The pad connection electrode PDE may be electrically connected to a pad CPD of the circuit board CB fixed to one side of the first substrate SUB1 through a wire WR.

A first insulating layer INS1 may be disposed on the first substrate SUB1 on which pixel electrodes 111, the first pads PD1, and first common connection electrodes CCE1 are not disposed. An upper surface of the first insulating layer INS1, an upper surface of each of the pixel electrodes 111, an upper surface of each of the first pads PD1, and an upper surface of each of the first common connection electrodes CCE1 may be flatly connected to each other. The first insulating layer INS1 may be formed as an inorganic film such as a silicon oxide film (SiO₂), an aluminum oxide film (Al₂O₃), or a hafnium oxide film (HfOₓ).

The common connection electrode CCE (e.g., CCE2) and the pad connection electrode PDE may be formed at the same layer and may be made of the same material.

The display device 100 may further include a second insulating layer INS2 covering side portions of each of the common connection electrodes CCE and the pad connection electrodes PDE. In one or more embodiments, the second insulating layer INS2 may cover the side portions of the first pad PD1.

Each of the first pad PD1 and the first common connection electrode CCE1 may be an exposed electrode exposed from the first substrate SUB1. The first pad PD1 and the first common connection electrode CCE1 may include the same material as pixel electrodes 111 to be described later. For example, the first pad PD1 and the first common connection electrode CCE1 may include aluminum (Al).

The pad connection electrode PDE may be disposed on the first pad PD1, and a second common connection electrode CCE2 may be disposed on the first common connection electrode CCE1. The pad connection electrode PDE may be in contact with the upper surface of the first pad PD1, and the second common connection electrode CCE2 may be in contact with the upper surface of the first common connection electrode CCE1. Each of the pad connection electrode PDE and the second common connection electrode CCE2 may include a first layer and a second layer.

Each first layer of the pad connection electrode PDE and the second common connection electrode CCE2 may include the same material as first connection electrodes 112-1. For example, each of the pad connection electrode PDE and the second common connection electrode CCE2 may include at least one of gold (Au), copper (Cu), aluminum (Al), or tin (Sn).

Each second layer of the pad connection electrode PDE and the second common connection electrode CCE2 may include the same material as second connection electrodes 112-2. For example, the second layer of each of the pad connection electrode PDE and the second common connection electrode CCE2 may include at least one of gold (Au), copper (Cu), aluminum (Al), or tin (Sn).

The pad connection electrode PDE may be connected to the circuit pad CPD of the circuit board CB through a conductive connection member such as the wire WR. That is, the first pad PD1, the pad connection electrode PDE, the wire WR, and the circuit pad CPD of the circuit board CB may be electrically connected to each other.

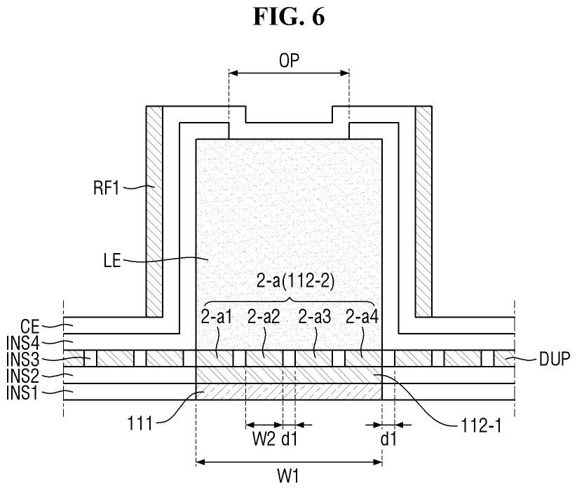

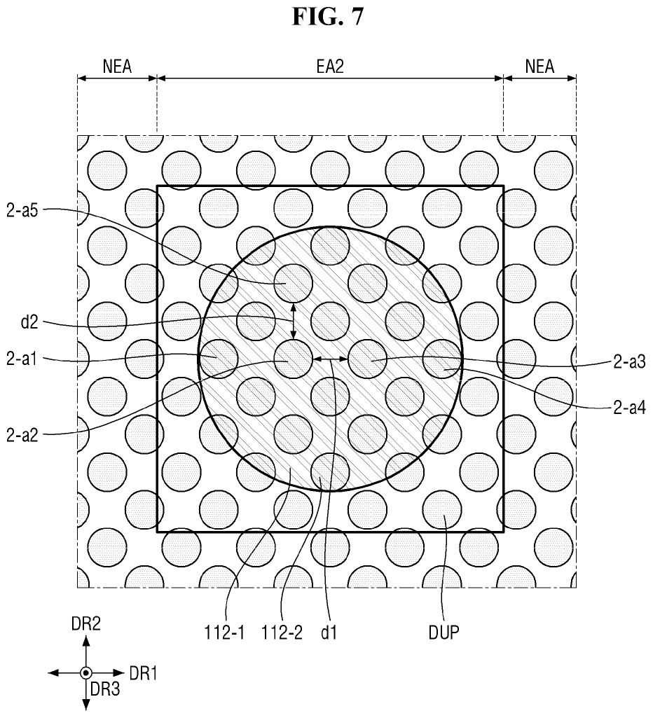

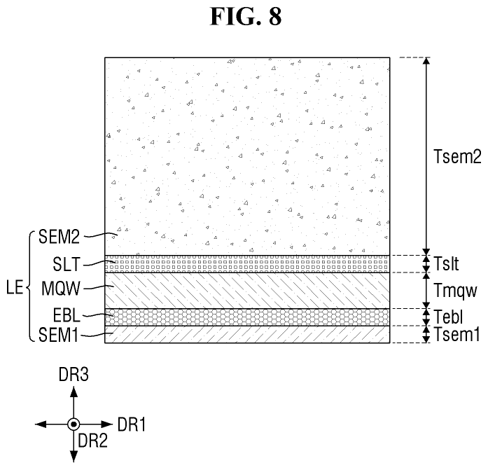

FIG. 5 is a cross-sectional view illustrating an example of the display panel taken along the line B-B′ of FIG. 3. FIG. 6 is an enlarged cross-sectional view illustrating a light emitting element of a second emission area of FIG. 5. FIG. 7 is a layout diagram illustrating pixels of the display panel including a first connection electrode and a second connection electrode of FIG. 6. FIG. 8 is an enlarged cross-sectional view illustrating an example of a light emitting element of FIG. 5 in detail.

Referring to FIGS. 5 to 8, the display panel 100 may include a semiconductor circuit substrate 110 and a light emitting element layer 120.

The semiconductor circuit substrate 110 may include a first substrate SUB1, a plurality of pixel circuit units PXC, pixel electrodes 111, a first insulating layer INS1, first connection electrodes 112-1, and second insulating layer INS2.

The first substrate SUB1 may be a silicon wafer substrate. The first substrate SUB1 may be made of single crystal silicon.

Each of the plurality of pixel circuit units PXC may be disposed on the first substrate 110. Each of the plurality of pixel circuit units PXC may include a complementary metal oxide semiconductor (CMOS) circuit formed using a semiconductor process. Each of the plurality of pixel circuit units PXC may include at least one transistor formed by a semiconductor process. In addition, each of the plurality of pixel circuit units PXC may further include at least one capacitor formed by a semiconductor process.

The plurality of pixel circuit units PXC may be disposed in the display area DA (see FIG. 1). Each of the plurality of pixel circuit units PXC may be connected to the pixel electrode 111 corresponding thereto. Each of the plurality of pixel circuit units PXC may apply a pixel voltage or an anode voltage to the pixel electrode 111.

Each of the pixel electrodes 111 may be disposed on the pixel circuit unit PXC corresponding thereto. Each of the pixel electrodes 111 may be an exposed electrode exposed from the pixel circuit unit PXC. That is, each of the pixel electrodes 111 may protrude from an upper surface of the pixel circuit unit PXC. Each of the pixel electrodes 111 may be formed integrally with the pixel circuit unit PXC. Each of the pixel electrodes 111 may receive the pixel voltage or the anode voltage supplied from the pixel circuit unit PXC. The pixel electrodes 111 may include aluminum (Al).

The first insulating layer INS1 may be disposed on the first substrate SUB1 on which the pixel electrodes 111 are not disposed. An upper surface of the first insulating layer INS1 and an upper surface of each of the pixel electrodes 111 may be flatly connected to each other (e.g., may be at the same level). Alternatively, the first insulating layer INS1 may be disposed to cover the pixel electrodes 111. In this case, at least partial areas of each of the pixel electrodes 111 and the first pads PD1 may be exposed without being covered by the first insulating layer INS1 through contact holes penetrating through the first insulating layer INS1.

Each of the first connection electrodes 112-1 may be disposed on the pixel electrode 111 corresponding thereto. The first connection electrodes 112-1 may serve as bonding metals for bonding the pixel electrodes 111 and the light emitting elements LE to each other together with second connection electrodes 112-2 to be described later in a manufacturing process. For example, the first connection electrodes 112-1 may include at least one of gold (Au), copper (Cu), aluminum (Al), or tin (Sn). Alternatively, the first connection electrodes 112-1 may include a first layer including one or more selected from among of gold (Au), copper (Cu), aluminum (Al), and tin (Sn) and a second layer including another one or more of gold (Au), copper (Cu), aluminum (Al), and tin (Sn). In this case, the second layer may be disposed on the first layer.

The second insulating layer INS2 may be disposed on the first insulating layer INS1 on which the first connection electrodes 112-1 are not disposed. An upper surface of the second insulating layer INS2 and an upper surface of each of the first connection electrodes 112-1 may be flatly connected to each other (e.g., may be at the same level). The second insulating layer INS2 may be formed as an inorganic film such as a silicon oxide film (SiO₂), an aluminum oxide film (Al₂O₃), or a hafnium oxide film (HfOₓ).

The light emitting element layer 120 may be a layer including the plurality of emission areas EA1, EA2, and EA3 to emit light. The light emitting element layer 120 may include second connection electrodes 112-2, dummy electrodes DUP, light emitting elements LE, a third insulating layer INS3, a fourth insulating layer INS4, a common electrode CE, wavelength conversion layers QDL, a light transmission layer TPL, a first reflective layer RF1, a second reflective layer RF2, and a plurality of color filters CF1, CF2, and CF3.

Each of the second connection electrodes 112-2 may be disposed on the first connection electrode 112-1 corresponding thereto. The second connection electrodes 112-2 may be in contact with an upper surface of the first connection electrode 112-1. Each of the second connection electrodes 112-2 may be connected to the light emitting element LE corresponding thereto. A plurality of sub-connection electrodes 2-a1, 2-a2, 2-a3, and 2-a4 of the second connection electrode 112-2 may be disposed on the first connection electrode 112-1 corresponding thereto and may be in contact with the light emitting element LE.

The plurality of sub-connection electrodes 2-a1, 2-a2, 2-a3, and 2-a4 may be spaced from each other in each of the first direction DR1 and the second direction DR2. An arrangement form of the plurality of sub-connection electrodes 2-a1, 2-a2, 2-a3, and 2-a4 may include first and second columns arranged side by side along the first direction DR1. The sub-connection electrodes 2-a1, 2-a2, 2-a3, and 2-a4 of the first and second columns may not be side by side in the second direction DR2 and may neighbor (e.g., be adjacent to) each other in a diagonal direction crossing the first direction DR1 and the second direction DR2. In one or more embodiments, the sub-connection electrodes 2-a1, 2-a2, 2-a3, and 2-a4 of the first column and the second column may be arranged side by side in the second direction DR2.

Each of the plurality of sub-connection electrodes 2-a1, 2-a2, 2-a3, and 2-a4 is formed in an island-shaped pattern. For example, the second connection electrode 112-2 may include a first sub-connection electrode 2-a1, a second sub-connection electrode 2-a2, a third sub-connection electrode 2-a3, and a fourth sub-connection electrode 2-a4 arranged in a row in the first direction DR1. In addition, the second connection electrode 112-2 may include a second sub-connection electrode 2-a2 and a fifth sub-connection electrode 2-a5 arranged in a row in the second direction DR2.

The first sub-connection electrode 2-a1 and the second sub-connection electrode 2-a2 may be spaced from each other by a an interval (e.g., a predetermined interval) d1 (hereinafter referred to as a “first interval”) in the first direction DR1. In addition, the second sub-connection electrode 2-a2 and the fifth sub-connection electrode 2-a5 may be spaced from each other by an interval (e.g., a predetermined interval) d2 (hereinafter referred to as a “second interval”) in the second direction DR2. The first interval and the second interval may be the same as or different from each other.

The plurality of sub-connection electrodes 2-a1, 2-a2, 2-a3, and 2-a4 may have the same width W2 in the first direction DR1. The width W2 of each of the plurality of sub-connection electrodes 2-a1, 2-a2, 2-a3, and 2-a4 in the first direction DR1 is smaller than a width W1 of the first connection electrode 112-1 in the first direction DR1. The width W1 of the first connection electrode 112-1 in the first direction DR1 may be 4 to 5 times the width W2 of each of the plurality of sub-connection electrodes 2-a1, 2-a2, 2-a3, and 2-a4 in the first direction DR1, but is not limited thereto. In addition, the sum of the widths W2, in the first direction DR1, of the plurality of sub-connection electrodes 2-a1, 2-a2, 2-a3, and 2-a4 of the second connection electrode 112-2 that are arranged in the first direction DR1 is smaller than the width W1 of the first connection electrode 112-1 in the first direction DR1. The sum of areas of upper surfaces of the plurality of sub-connection electrodes 2-a1, 2-a2, 2-a3, and 2-a4 included in the second connection electrode 112-2 may be greater than ½ of an area of an upper surface of the corresponding first connection electrode 112-1, but is not limited thereto.

A plurality of dummy electrodes DUP may be disposed on the second insulating layer INS2 on which the second connection electrodes 112-2 are not disposed. Each of the dummy electrodes DUP may protrude from the upper surface of the second insulating layer INS2. The plurality of dummy electrodes DUP may include the same material as the plurality of sub-connection electrodes 2-a1, 2-a2, 2-a3, and 2-a4. The plurality of dummy electrodes DUP may be spaced from each other in each of the first direction DR1 and the second direction DR2, like the plurality of sub-connection electrodes 2-a1, 2-a2, 2-a3, and 2-a4. The plurality of dummy electrodes DUP are formed in an island-shaped pattern.

In addition, the plurality of dummy electrodes DUP may be spaced from each other by a first interval d1 in each of the first direction DR1, like the plurality of sub-connection electrodes 2-a1, 2-a2, 2-a3, and 2-a4. Here, the first interval d1 may be smaller than the width W2 of each of the sub-connection electrodes 2-a1, 2-a2, 2-a3, and 2-a4 in the first direction DR1. In addition, the dummy electrodes DUP may be spaced from each other by a second interval (e.g., the second interval d2) in the second direction DR2. An arrangement form of the plurality of dummy electrodes DUP is the same as that of the plurality of sub-connection electrodes 2-a1, 2-a2, 2-a3, and 2-a4. The arrangement form of the plurality of dummy electrodes DUP may include first and second columns arranged side by side in the first direction DR1. The dummy electrodes DUP of the first and second columns may not be side by side in the second direction DR2 and may neighbor (e.g., be adjacent to) each other in the diagonal direction crossing the first direction DR1 and the second direction DR2. In one or more embodiments, the dummy electrodes DUP of the first column and the second column may be arranged side by side in the second direction DR2.

A size and a shape of the dummy electrode DUP are the same as those of any one of the plurality of sub-connection electrodes 2-a1, 2-a2, 2-a3, and 2-a4. A dummy electrode neighboring, in the first direction DR1, to a sub-connection electrode (e.g., the fourth sub-connection electrode 2-a4) positioned at the outermost side of the second connection electrode 112-2 may be spaced from the sub-connection electrode by the first interval d1 in the first direction DR1. A dummy electrode neighboring, in the second direction DR2, to a sub-connection electrode positioned at the outermost side of the second connection electrode 112-2 may be spaced from the sub-connection electrode by the second interval d2 in the second direction DR2.

The second connection electrodes 112-2 may serve as bonding metals for bonding the pixel electrodes 111 and the light emitting elements LE to each other together with the first connection electrodes 112-1 in a manufacturing process. For example, the second connection electrodes 112-2 may include at least one of gold (Au), copper (Cu), aluminum (Al), or tin (Sn).

The second connection electrode 112-2 and the dummy electrode DUP may be formed in the same manufacturing process and include the same material. Accordingly, the dummy electrode DUP may include at least one of gold (Au), copper (Cu), aluminum (Al), or tin (Sn).

The third insulating layer INS3 may be disposed between the plurality of sub-connection electrodes 2-a1, 2-a2, 2-a3, and 2-a4. In addition, the third insulating layer INS3 may be disposed between the dummy electrodes DUP. The upper surfaces of the plurality of sub-connection electrodes 2-a1, 2-a2, 2-a3, and 2-a4, upper surfaces of the dummy electrodes DUP, and an upper surface of the third insulating layer INS3 may be flat connected to each other (e.g., may be at the same level). The third insulating layer INS3 may be formed as an inorganic film such as a silicon oxide film (SiO₂), an aluminum oxide film (Al₂O₃), or a hafnium oxide film (HfOₓ).

Each of the light emitting elements LE may be disposed on the second connection electrode 112-2. The light emitting element LE may be a vertical light emitting diode element extending in the third direction DR3. That is, a length of the light emitting element LE in the third direction DR3 may be greater than a length of the light emitting element LE in a horizontal direction. The length in the horizontal direction refers to a length in the first direction DR1 or a length in the second direction DR2. For example, the length of the light emitting element LE in the third direction DR3 may be approximately 1 to 5 μm.

The light emitting element LE may be a micro light emitting diode element or a nano light emitting diode element. The light emitting element LE includes a first semiconductor layer SEM1, an electron blocking layer EBL, an active layer MQW, a superlattice layer SLT, and a second semiconductor layer SEM2 arranged along the third direction DR3, as illustrated in FIG. 8. The first semiconductor layer SEM1, the electron blocking layer EBL, the active layer MQW, the superlattice layer SLT, and the second semiconductor layer SEM2 may be sequentially stacked along the third direction DR3.

The first semiconductor layer SEM1 may be disposed on the second connection electrode 112-2. The first semiconductor layer SEM1 may be doped with a first conductivity-type dopant such as Mg, Zn, Ca, Se, or Ba. For example, the first semiconductor layer SEM1 may be made of p-GaN doped with p-type Mg. A thickness Tsem1 of the first semiconductor layer SEM1 may be approximately 30 to 200 nm.

The electron blocking layer EBL may be disposed on the first semiconductor layer SEM1. The electron blocking layer EBL may be a layer for suppressing or preventing too many electrons from flowing to the active layer MQW. For example, the electron blocking layer EBL may be made of p-AlGaN doped with p-type Mg. A thickness Tebl of the electron blocking layer EBL may be approximately 10 to 50 nm. The electron blocking layer EBL may be omitted.

The active layer MQW may be disposed on the electron blocking layer EBL. The active layer MQW may emit light by a combination of electron-hole pairs according to electrical signals applied through the first semiconductor layer SEM1 and the second semiconductor layer SEM2. The active layer MQW may emit first light having a central wavelength band in the range of 450 nm to 495 nm, that is, light of a blue wavelength band.

The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be made of InGaN, and the barrier layer may be made of GaN or AlGaN, but the present disclosure is not limited thereto. A thickness of the well layer may be approximately 1 to 4 nm, and a thickness of the barrier layer may be 3 to 10 nm. Therefore, a thickness Tmqw of the active layer MQW may be approximately 4 to 14 nm.

Alternatively, the active layer MQW may have a structure in which semiconductor materials having large band gap energy and semiconductor materials having small band gap energy are alternately stacked, and may include other Group III to Group V semiconductor materials depending on a wavelength band of emitted light. The light emitted by the active layer MQW is not limited to the first light (e.g., the light of the blue wavelength band), and in some cases, the active layer MQW may emit the second light (e.g., the light of a green wavelength band) or the third light (e.g., the light of a red wavelength band).

The superlattice layer SLT may be disposed on the active layer MQW. The superlattice layer SLT may be a layer for alleviating stress between the second semiconductor layer SEM2 and the active layer MQW. For example, the superlattice layer SLT may be made of InGaN or GaN. A thickness Tslt of the superlattice layer SLT may be approximately 50 to 200 nm. The superlattice layer SLT may be omitted.

The second semiconductor layer SEM2 may be disposed on the superlattice layer SLT. The second semiconductor layer SEM2 may be doped with a second conductivity-type dopant such as Si, Ge, or Sn. For example, the second semiconductor layer SEM2 may be made of n-GaN doped with n-type Si. A thickness Tsem2 of the second semiconductor layer SEM2 may be approximately 500 nm to 1 μm.

The fourth insulating layer INS4 may be disposed on side surfaces of each of the light emitting elements LE. The fourth insulating layer INS4 may have an opening OP on an upper surface of each of the light emitting elements LE. The light emitting element LE may be in contact with a common electrode CE to be described later through the opening OP. The fourth insulating layer INS4 may be formed as an inorganic film such as a silicon oxide film (SiO₂), an aluminum oxide film (Al₂O₃), or a hafnium oxide film (HfOₓ), but is not limited thereto.

The common electrode CE may be disposed on the upper surface of each of the light emitting elements LE, and an upper surface of the fourth insulating layer INS4. The common electrode CE may be disposed to completely cover each of the light emitting elements LE.

The common electrode CE may include a transparent conductive material. For example, the common electrode CE may include a transparent conductive oxide (TCO) such as indium tin oxide (ITO) or indium zinc oxide (IZO).

The first reflective layer RF1 may be disposed to be in contact with the common electrode CE so as to be around (e.g., to surround) the side surfaces of each of the light emitting elements LE. The first reflective layer RF1 serves to reflect light traveling toward left and right side surfaces rather than in an upward direction, from among the light emitted from the light emitting element LE. The first reflective layer RF1 may include a metal material having high reflectivity, such as aluminum (Al). A thickness of the first reflective layer RF1 may be approximately 0.1 μm.

The light transmission layer TPL may be disposed on the common electrode CE in each of the first emission areas EA1. The light transmission layer TPL may overlap the light emitting element LE in the third direction DR3 in each of the first emission areas EA1. The light transmission layer TPL may be disposed to completely cover the light emitting element LE in each of the first emission areas EA1.

The light transmission layer TPL may include a light-transmitting organic material. For example, the light transmission layer TPL may include an epoxy-based resin, an acrylic resin, a cardo-based resin, an imide-based resin, or the like.

The wavelength conversion layer QDL may be disposed on the common electrode CE in each of the second emission areas EA2 and the third emission areas EA3. The wavelength conversion layer QDL may overlap the light emitting element LE in the third direction DR3 in each of the second emission areas EA2 and the third emission areas EA3. The wavelength conversion layer QDL may be disposed to completely cover the light emitting element LE in each of the second emission areas EA2 and the third emission areas EA3.

The wavelength conversion layer QDL may include a base resin BRS and first wavelength conversion particles WCP1. The base resin BRS may include a light-transmitting organic material. For example, the base resin BRS may include an epoxy-based resin, an acrylic resin, a cardo-based resin, an imide-based resin, or the like.

The first wavelength conversion particles WCP1 may convert the first light emitted from the light emitting element LE into the fourth light. For example, the first wavelength conversion particles WCP1 may convert the light of the blue wavelength band into the light of the yellow wavelength band. The first wavelength conversion particle WCP1 may be a quantum dot (QD), a quantum rod, a fluorescent material, or a phosphorescent material. The quantum dot may include Group IV nanocrystals, Group II-VI compound nanocrystals, Group III-V compound nanocrystals, Group IV-VI compound nanocrystals, or combinations thereof.

The quantum dot may include a core and a shell overcoating the core. The core may include, for example, at least one of CdS, CdSe, CdTe, ZnS, ZnSe, ZnTe, GaN, GaP, GaAs, GaSb, AlN, AlP, AlAs, AlSb, InP, InAs, InSb, SiC, Ca, Se, In, P, Fe, Pt, Ni, Co, Al, Ag, Au, Cu, FePt, Fe₂O₃, Fe₃O₄, Si, or Ge, but is not limited thereto. The shell may include, for example, at least one of ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, or PbTe, but is not limited thereto.

The wavelength conversion layer QDL may further include scatterers for scattering the light of the light emitting element LE in a random direction. In this case, the scatterers may include metal oxide particles or organic particles. For example, a metal oxide may be titanium oxide (TiO₂), zirconium oxide (ZrO₂), silicon dioxide (SiO₂), aluminum oxide (Al₂O₃), indium oxide (In₂O₃), zinc oxide (ZnO), and/or tin oxide (SnO₂). In addition, the organic particles may include an acrylic resin or a urethane-based resin. The scatterer may have a diameter of several to several tens of nanometers.

The second reflective layer RF2 may be disposed on side surfaces of the light transmission layer TPL in each of the first emission areas EA1, while may be disposed on side surfaces of the wavelength conversion layer QDL in each of the second emission areas EA2 and the third emission areas EA3. The second reflective layer RF2 serves to reflect light traveling toward left and right side surfaces rather than in an upward direction, from among the light emitted from the light emitting element LE, similar to the first reflective layer RF1. The second reflective layer RF2 may include a metal material having high reflectivity, such as aluminum (Al). A thickness of the second reflective layer RF2 may be approximately 0.1 μm.

The plurality of color filters CF1, CF2, and CF3 may include first color filters CF1, second color filters CF2, and third color filters CF3. In one or more embodiments, a buffer layer BF may be disposed between the light transmission layer TPL and the wavelength conversion layer QDL, and the plurality of color filters CF1, CF2, and CF3.

Each of the first color filters CF1 may be disposed on the light transmission layer TPL in the first emission area EA1. Each of the first color filters CF1 may transmit the first light therethrough and absorb or block the second light and the third light. For example, each of the first color filters CF1 may transmit the light of the blue wavelength band therethrough and absorb or block the light of the green and red wavelength bands. Therefore, each of the first color filters CF1 may transmit the first light emitted from the light emitting element LE therethrough. That is, the first light emitted from the light emitting element LE in the first emission area EA1 is not converted by a separate wavelength conversion layer and may be transmitted through the first color filter CF1 through the light transmission layer TPL. Accordingly, each of the first emission areas EA1 may emit the first light.

Each of the second color filters CF2 may be disposed on the wavelength conversion layer QDL in the second emission area EA2. Each of the second color filters CF2 may transmit the second light therethrough and absorb or block the first light and the third light. For example, each of the second color filters CF2 may transmit the light of the green wavelength band therethrough and absorb or block the light of the blue and red wavelength bands. Therefore, each of the second color filters CF2 may absorb or block first light that is not converted by the wavelength conversion layer QDL from among the first light emitted from the light emitting element LE. In addition, each of the second color filters CF2 may transmit the second light corresponding to the green wavelength band from among the fourth light converted by the wavelength conversion layer QDL therethrough, and absorb or block the third light corresponding to the blue wavelength band from among the fourth light. Accordingly, each of the second emission areas EA2 may emit the second light.

Each of the third color filters CF3 may be disposed on the wavelength conversion layer QDL in the third emission area EA3. Each of the third color filters CF3 may transmit the third light therethrough and absorb or block the first light and the second light. For example, each of the third color filters CF3 may transmit the light of the red wavelength band therethrough and absorb or block the light of the blue and green wavelength bands. Therefore, each of the third color filters CF3 may absorb or block first light that is not converted by the wavelength conversion layer QDL from among the first light emitted from the light emitting element LE. In addition, each of the third color filters CF3 may transmit the third light corresponding to the red wavelength band from among the fourth light converted by the wavelength conversion layer QDL therethrough, and absorb or block the second light corresponding to the green wavelength band from among the fourth light. Accordingly, each of the third emission areas EA3 may emit the third light.

A black matrix BM may be disposed between the plurality of color filters CF1, CF2, and CF3. For example, the black matrix BM may be disposed between the first color filter CF1 and the second color filter CF2, between the second color filter CF2 and the third color filter CF3, and between the first color filter CF1 and the third color filters CF3. The black matrix BM may include an inorganic black pigment such as carbon black or an organic black pigment.

In one or more embodiments, in order to simplify a manufacturing process, in FIG. 5, a wavelength conversion layer QDL may be disposed instead of the light transmission layer TPL in each of the first emission areas EA1.

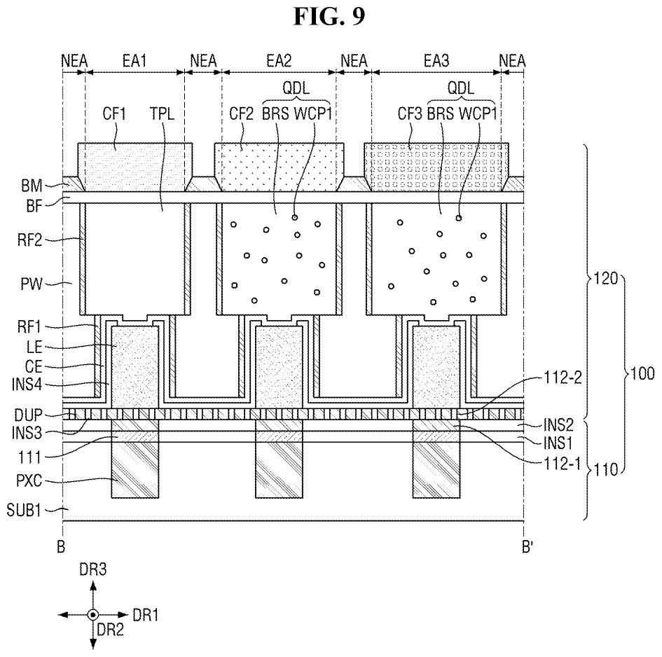

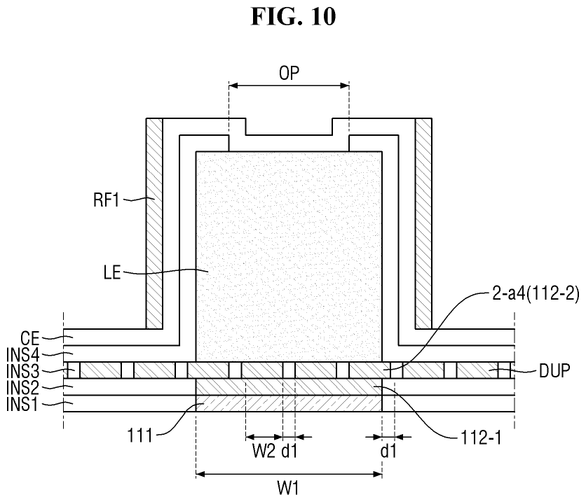

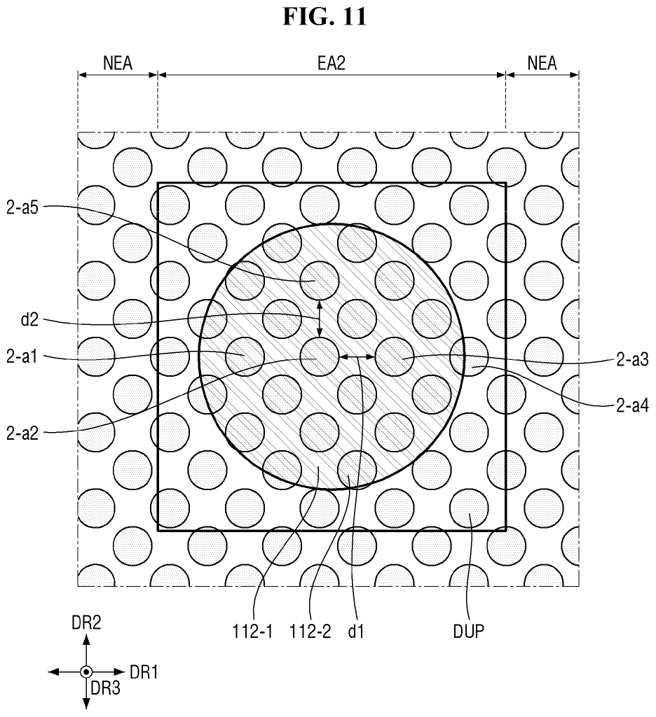

FIG. 9 is a cross-sectional view illustrating an example of the display panel taken along the line B-B′ of FIG. 3. FIG. 10 is an enlarged cross-sectional view illustrating a light emitting element of a second emission area of FIG. 9. FIG. 11 is a layout diagram illustrating pixels of the display panel including a first connection electrode and a second connection electrode of FIG. 10.

Referring to FIGS. 9 to 11, a display panel according to an example is substantially the same as the display panel illustrated in FIGS. 5 to 7 except that some (e.g., the fourth sub-connection electrode 2-a4) of the plurality of sub-connection electrodes 2-a1, 2-a2, 2-a3, and 2-a4 included in the second connection electrode 112-2 are disposed to protrude outside the first connection electrode 112-1 or outside the light emitting element LE (e.g., the fourth sub-connection electrode 2-a4 does not completely overlap first connection electrode 112-1 and the light emitting element LE in the third direction DR3), and an overlapping description thereof will thus be omitted.

Referring to FIGS. 9 to 11, even when the fourth sub-connection electrode 2-a4 is disposed outside the first connection electrode 112-1 or outside the light emitting element LE, the second connection electrode 112-2 may normally bond the pixel circuit unit PXC and the corresponding light emitting element LE to each other by the plurality of sub-connection electrodes 2-a1, 2-a2, 2-a3, and 2-a4 overlapping the first connection electrode 112-1.

In one or more embodiments, because the first connection electrode 112-1 is planarized by the second insulating layer INS2 and the plurality of sub-connection electrodes 2-a1, 2-a2, 2-a3, and 2-a4 are planarized by the third insulating layer INS3, even when some sub-connection electrodes (e.g., the fourth sub-connection electrode 2-a4) are disposed to protrude outside the light emitting element LE, a tilting defect that the light emitting element LE is tilted may not occur.

Hereinafter, display devices according to one or more embodiments will be described with reference to other drawings.

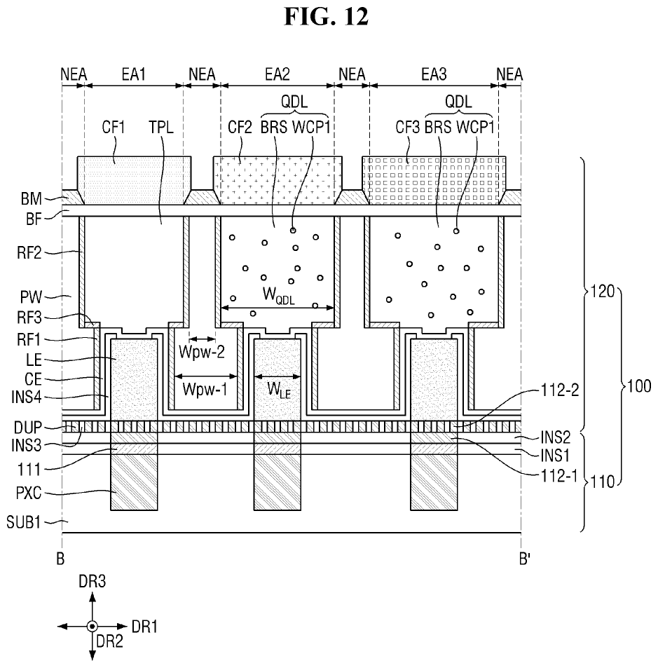

FIG. 12 is a cross-sectional view illustrating an example of the display panel taken along the line B-B′ of FIG. 3.

FIG. 12 is a schematic cross-sectional view illustrating a display device according to one or more embodiments. Referring to FIG. 12, the present embodiment is different from the above-described embodiment of FIG. 5 in that a third reflective layer RF3 is further disposed on a bottom portion of the wavelength conversion layer QDL and the light transmission layer TPL. Hereinafter, a description of the same configuration will be simplified or omitted, and configurations different from those described above will be described in detail.

Referring to FIG. 12, in one or more embodiments, a length W_{QDL} of the wavelength conversion layer QDL in the first direction DR1 may be greater than a length W_{LE} of the light emitting element LE in the first direction DR1. A width W_{PW}−1 of a partition wall PW between the light emitting elements LE may be wider than a width W_{PW}−2 of a partition wall PW between the wavelength conversion layers QDL and between the wavelength conversion layer QDL and the light transmission layer TPL.

The third reflective layer RF3 may be disposed on a bottom of the light transmission layer TPL and the wavelength conversion layer QDL that does not overlap the light emitting element LE. The first reflective layer RF1 and the second reflective layer RF2 are disposed to extend in the second direction DR2 and the third direction DR3, while the third reflective layer RF3 is disposed to extend in the first direction DR1 and the second direction DR2. The third reflective layer RF3 may be disposed in the emission area. The third reflective layer RF3 may be in contact with the partition wall PW, the light transmission layer TPL, and the wavelength conversion layer QDL. The third reflective layer RF3 may be made of the same material as the first reflective layer RF1 and the second reflective layer RF2, but is not limited thereto. The third reflective layer RF3 may include a metal material having high reflectivity, such as aluminum (Al). A thickness of the third reflective layer RF3 may be approximately 0.1 μm.

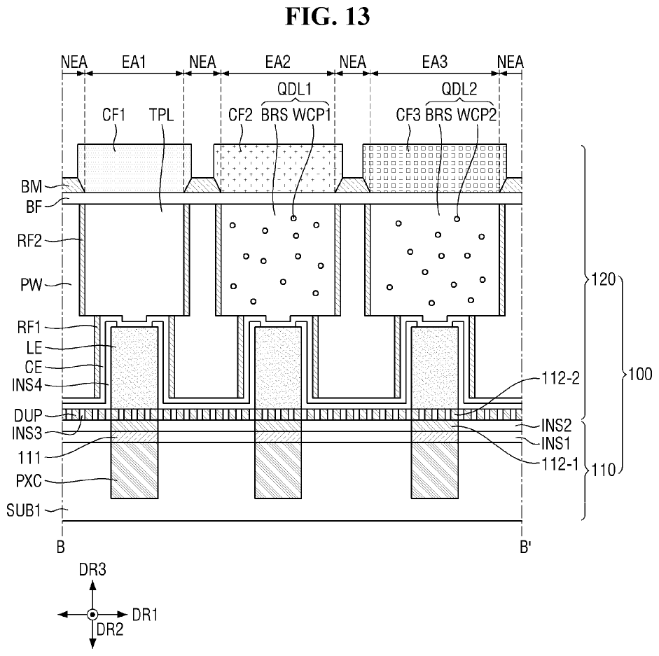

FIG. 13 is a cross-sectional view illustrating an example of the display panel taken along the line B-B′ of FIG. 3.

Referring to FIG. 13, the present embodiment is different from an embodiment of FIG. 5 in that each of the plurality of pixels PX includes light emitting elements LE emitting light and a first wavelength conversion layer QDL1 and a second wavelength conversion layer QDL2 are disposed in the second emission area EA2 and the third emission area EA3, respectively. In FIG. 13, a description of contents overlapping those of FIG. 5 will be omitted.

The first wavelength conversion layer QDL1 may be disposed on the common electrode CE in each of the second emission areas EA2. The first wavelength conversion layer QDL1 may overlap the light emitting element LE in the third direction DR3 in each of the second emission areas EA2. The first wavelength conversion layer QDL1 may be disposed to completely cover the light emitting element LE in each of the second emission areas EA2.

The first wavelength conversion layer QDL1 may include a base resin BRS and first wavelength conversion particles WCP1. The first wavelength conversion particles WCP1 may convert the first light emitted from the light emitting element LE into the second light. For example, the first wavelength conversion particles WCP1 may convert the light of the blue wavelength band into the light of the green wavelength band.

The second wavelength conversion layer QDL2 may be disposed on the common electrode CE in each of the third emission areas EA3. The second wavelength conversion layer QDL2 may overlap the light emitting element LE in the third direction DR3 in each of the third emission areas EA3. The second wavelength conversion layer QDL2 may be disposed to completely cover the light emitting element LE in each of the third emission areas EA3.

The second wavelength conversion layer QDL2 may include a base resin BRS and second wavelength conversion particles WCP2. The second wavelength conversion particles WCP2 may convert the first light emitted from the light emitting element LE into the third light. For example, the second wavelength conversion particles WCP2 may convert the light of the blue wavelength band into the light of the red wavelength band.

The second light converted by the first wavelength conversion particles WCP1 of the first wavelength conversion layer QDL1 from among the first light emitted from the light emitting element LE in the second emission area EA2 may be transmitted through the second color filter CF2. The first light that is not converted by the first wavelength conversion layer QDL1 from among the first light emitted from the light emitting element LE in the second emission area EA2 may be absorbed or blocked by the second color filter CF2. Therefore, the second emission area EA2 may emit the second light.

The third light converted by the second wavelength conversion layer QDL2 from among the first light emitted from the light emitting element LE in the third emission area EA3 may be transmitted through the third color filter CF3. The first light that is not converted by the second wavelength conversion layer QDL2 from among the first light emitted from the light emitting element LE in the third emission area EA3 may be absorbed or blocked by the third color filter CF3. Therefore, the third emission area EA3 may emit the third light.

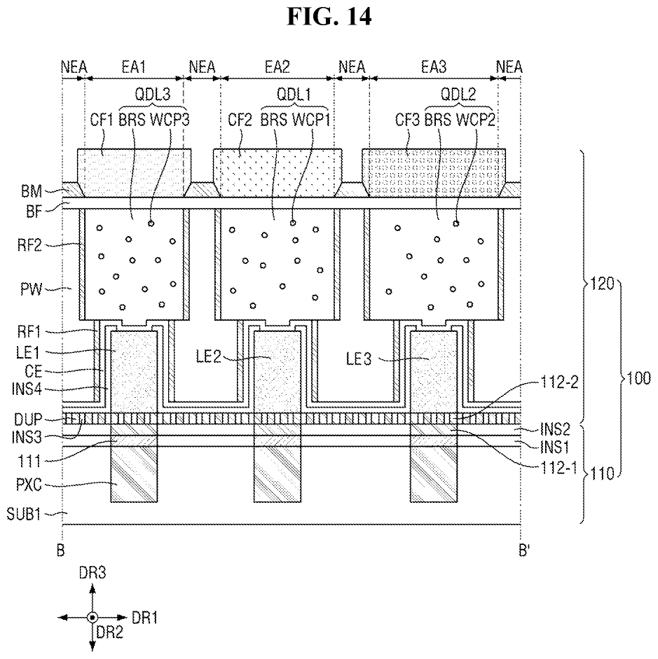

FIG. 14 is a cross-sectional view illustrating an example of the display panel taken along the line B-B′ of FIG. 3.

Referring to FIG. 14, the present embodiment is different from an embodiment of FIG. 13 in that each of the plurality of pixels PX includes light emitting elements LE1, LE2, and LE3 emitting light and a third wavelength conversion layer QDL3 is disposed in each of the first emission areas EA1. In FIG. 14, a description of contents overlapping those of FIG. 13 will be omitted.

Referring to FIG. 14, the first light emitting element LE1 may emit the first light. The first light may be light of a blue wavelength band. For example, a main peak wavelength (B-peak) of the first light may be positioned at approximately 370 nm to 460 nm, but an embodiment of the present disclosure is not limited thereto.

The second light emitting element LE2 may emit second light. The second light may be light of a green wavelength band. For example, a main peak wavelength (G-peak) of the second light may be positioned at approximately 480 nm to 560 nm, but the present disclosure is not limited thereto.

The third light emitting element LE3 may emit third light. The third light may be light of a red wavelength band. For example, a main peak wavelength (R-peak) of the third light may be positioned at approximately 60 nm to 750 nm, but the present disclosure is not limited thereto. The third wavelength conversion layer QDL3 may be disposed on the common electrode CE in each of the first emission areas EA1.

Each of the first emission areas EA1 may include the first light emitting element LE1, the third wavelength conversion layer QDL3, and the first color filter CF1.

The third wavelength conversion layer QDL3 may overlap the first light emitting element LE1 in the third direction DR3 in each of the first emission areas EA1. The third wavelength conversion layer QDL3 may be disposed to completely cover the first light emitting element LE1 in each of the first emission areas EA1.

The third wavelength conversion layer QDL3 may include a base resin BRS and third wavelength conversion particles WCP3. The third wavelength conversion particles WCP3 may convert light of other wavelengths into the first light, and the first color filter CF1 may transmit the first light therethrough. Therefore, each of the first emission areas EA1 may emit the first light. Accordingly, a color purity of the first light emitted from the first light emitting element LE1 and passing through the first color filter CF1 is improved.

Each of the second emission areas EA2 may include the second light emitting element LE2, the first wavelength conversion layer QDL1, and the second color filter CF2.

The first wavelength conversion layer QDL1 may overlap the second light emitting element LE2 in the third direction DR3 in each of the second emission areas EA2. The first wavelength conversion layer QDL1 may be disposed to completely cover the second light emitting element LE2 in each of the second emission areas EA2.

The first wavelength conversion layer QDL1 may include a base resin BRS and first wavelength conversion particles WCP1. The first wavelength conversion particles WCP1 may convert light of other wavelengths into the second light, and the second color filter CF2 may transmit the second light therethrough. Therefore, each of the second emission areas EA2 may emit the second light. Accordingly, a color purity of the second light emitted from the second light emitting element LE2 and passing through the second color filter CF2 is improved.

Each of the third emission areas EA3 may include the third light emitting element LE3, the second wavelength conversion layer QDL2, and the third color filter CF3.

The second wavelength conversion layer QDL2 may overlap the third light emitting element LE3 in the third direction DR3 in each of the third emission areas EA3. The second wavelength conversion layer QDL2 may be disposed to completely cover the third light emitting element LE3 in each of the third emission areas EA3.

The second wavelength conversion layer QDL2 may include a base resin BRS and second wavelength conversion particles WCP2. The second wavelength conversion particles WCP2 may convert light of other wavelengths into the third light, and the third color filter CF3 may transmit the third light therethrough. Therefore, each of the third emission areas EA3 may emit the third light. Accordingly, a color purity of the third light emitted from the third light emitting element LE3 and passing through the third color filter CF3 is improved.

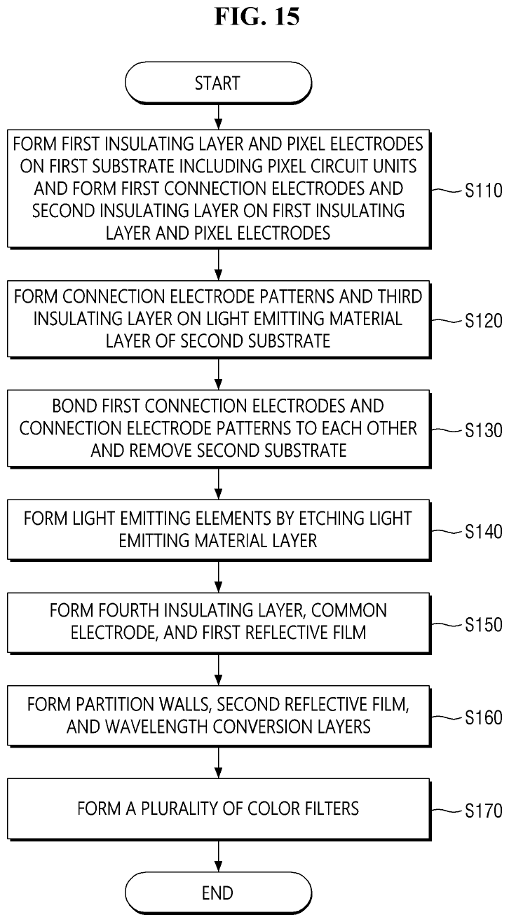

FIG. 15 is a flowchart illustrating a method for manufacturing a display device according to one or more embodiments.

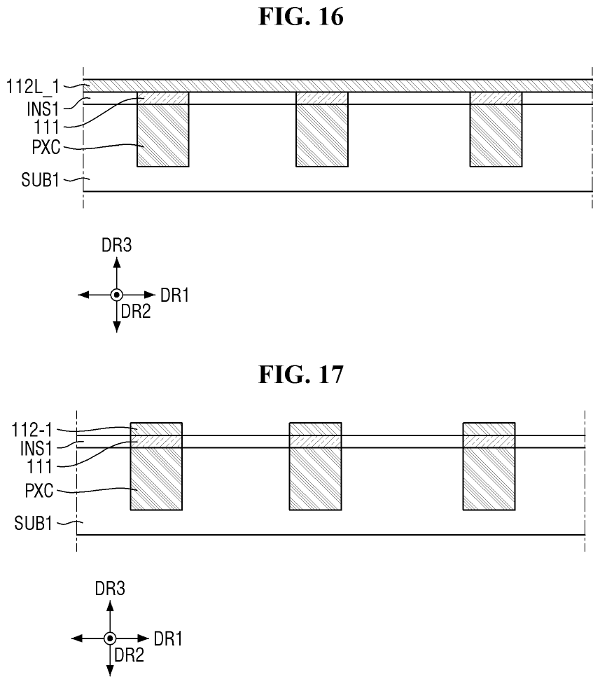

FIGS. 16 to 33 are cross-sectional views for describing the method for manufacturing a display device according to one or more embodiments.

As illustrated in FIGS. 16-18, the first insulating layer INS1 and the pixel electrodes 111 are formed on the first substrate SUB1 including the pixel circuit units PXC and the first connection electrodes 112-1 and the second insulating layer INS2 are formed on the first insulating layer INS1 and the pixel electrodes 111 (S110 of FIG. 15).

More specifically, first, the pixel electrodes 111 are formed on the pixel circuit units PXC, and the first insulating layer INS1 is formed on the first substrate SUB1 on which the pixel electrodes 111 are not disposed. An upper surface of the first insulating layer INS1 and an upper surface of each of the pixel electrodes 111 may be flatly connected to each other (e.g., may be at the same level). That is, a height difference between an upper surface of the first substrate SUB1 and the upper surface of the pixel electrode 111 may be eliminated by the first insulating layer INS1. The first insulating layer INS1 may be formed as an inorganic film such as a silicon oxide film (SiO₂), an aluminum oxide film (Al₂O₃), or a hafnium oxide film (HfOₓ).

Then, a first connection electrode layer 112L_1 is deposited on the pixel electrodes 111 and the first insulating layer INS1. The first connection electrode layer 112L_1 may include at least one of gold (Au), copper (Cu), tin (Sn), silver (Ag), aluminum (Al), or titanium (Ti).

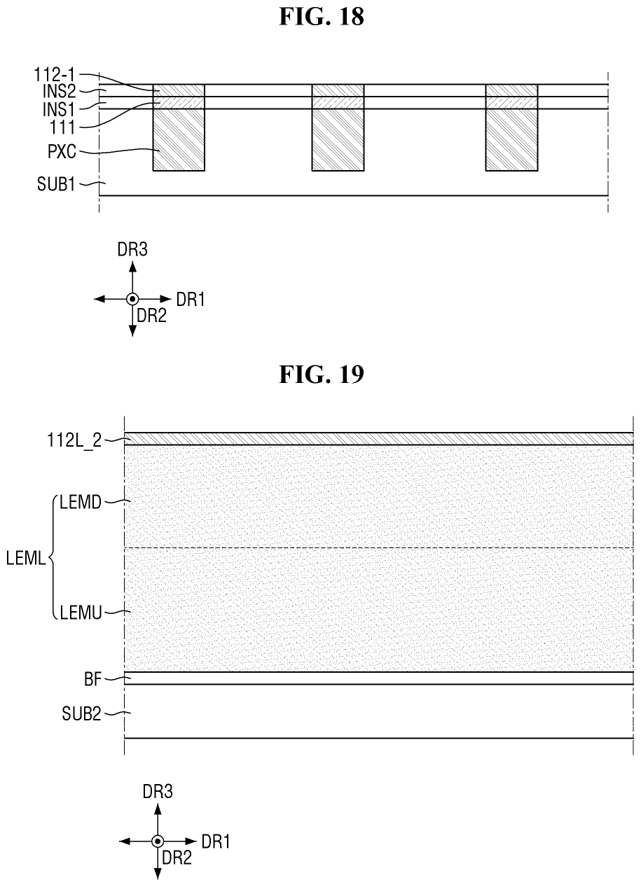

Referring to FIGS. 17 and 18, the first connection electrodes 112-1 are formed by etching the first connection electrode layer 112L_1, and the second insulating layer INS2 is formed on the first insulating layer INS1 on which the first connection electrodes 112-1 are not disposed. Here, the etching may be dry etching, which may be performed using sputtering etching, reactive radical etching, reactive ion etching, or Cl₂ gas-based inductively coupled plasma reactive ion etching (ICP-RIE) equipment. An upper surface of the second insulating layer INS2 and an upper surface of each of the first connection electrodes 112-1 may be flatly connected to each other (e.g., may be at the same level). The second insulating layer INS2 may be formed as an inorganic film such as a silicon oxide film (SiO₂), an aluminum oxide film (Al₂O₃), or a hafnium oxide film (HfOₓ).

Referring to FIGS. 19 to 21, connection electrode patterns 112-2P and a third insulating layer INS3 are formed on a light emitting material layer LEML of a second substrate SUB2 (S120 of FIG. 15).

First, referring to FIG. 19, a second connection electrode layer 112L_2 is deposited on the light emitting material layer LEML of the second substrate SUB2.

More specifically, a buffer layer BF may be formed on one surface of the second substrate SUB2. The second substrate SUB2 may be a silicon substrate or a sapphire substrate. The buffer layer BF may be formed as an inorganic film such as a silicon oxide film (SiO₂), an aluminum oxide film (Al₂O₃), and/or a hafnium oxide film (HfOₓ).

The light emitting material layer LEML may be disposed on the buffer layer BF. The light emitting material layer LEML may include a first semiconductor material layer LEMD and a second semiconductor material layer LEMU. The second semiconductor material layer LEMU may be disposed on the buffer layer BF, and the first semiconductor material layer LEMD may be disposed on the second semiconductor material layer LEMU. A thickness of the second semiconductor material layer LEMU may be greater than a thickness of the first semiconductor material layer LEMD.

The first semiconductor material layer LEMD may include a first semiconductor layer SEM1, an electron blocking layer EBL, an active layer MQW, a superlattice layer SLT, and a second semiconductor layer SEM2, as illustrated in FIG. 8. The second semiconductor material layer LEMU may be an undoped semiconductor layer. For example, the second semiconductor material layer LEMU may be made of undoped-GaN that is not doped.

The second connection electrode layer 112L_2 may be deposited on the first semiconductor material layer LEMD. The second connection electrode layer 112L_2 may include at least one of gold (Au), copper (Cu), tin (Sn), silver (Ag), aluminum (Al), or titanium (Ti).

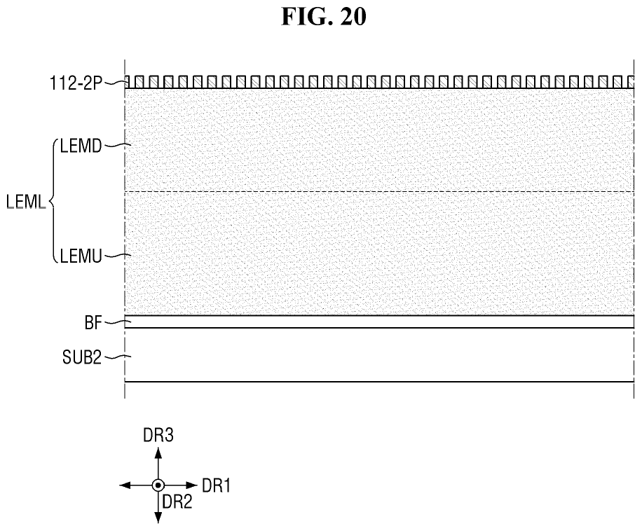

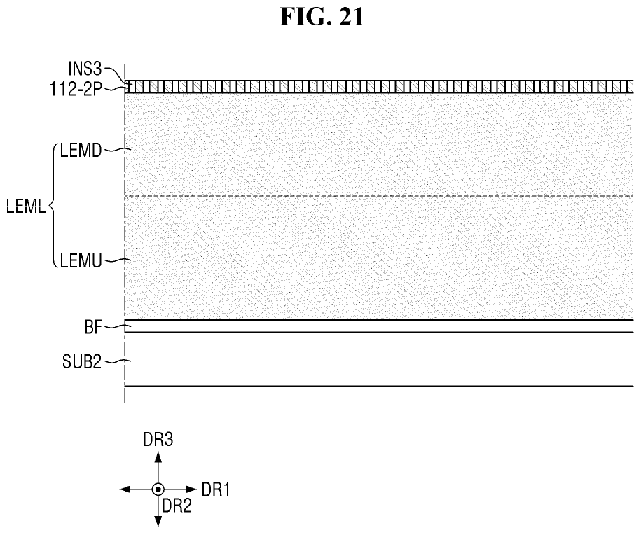

Next, referring to FIGS. 20 and 21, the connection electrode patterns 112-2P are formed by etching the second connection electrode layer 112L_2, and the third insulating layer INS3 is formed on the light emitting material layer LEML on which the connection electrode patterns 112-2P are not disposed. Here, the etching may be dry etching, which may be performed using sputtering etching, reactive radical etching, reactive ion etching, or Cl₂ gas-based inductively coupled plasma reactive ion etching (ICP-RIE) equipment. An upper surface of the third insulating layer INS3 and an upper surface of each of the connection electrode patterns 112-2P may be flatly connected to each other. The third insulating layer INS3 may be formed as an inorganic film such as a silicon oxide film (SiO₂), an aluminum oxide film (Al₂O₃), or a hafnium oxide film (HfOₓ).

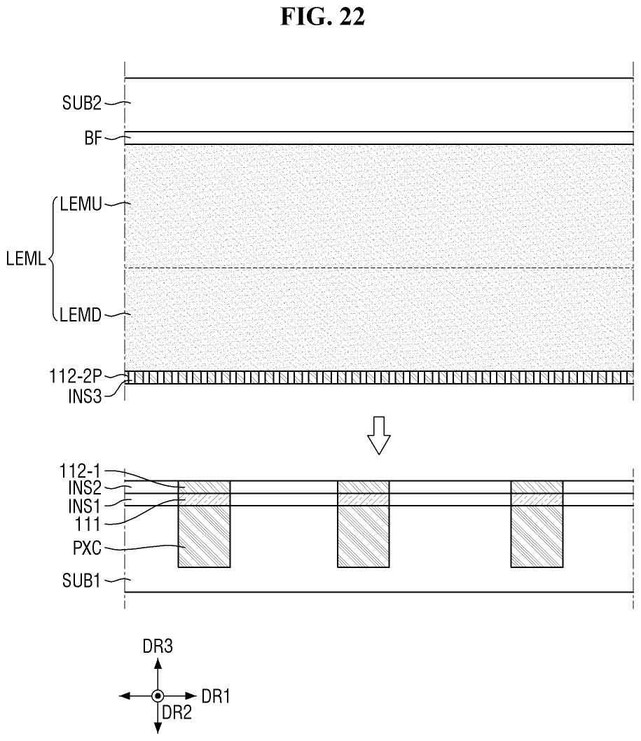

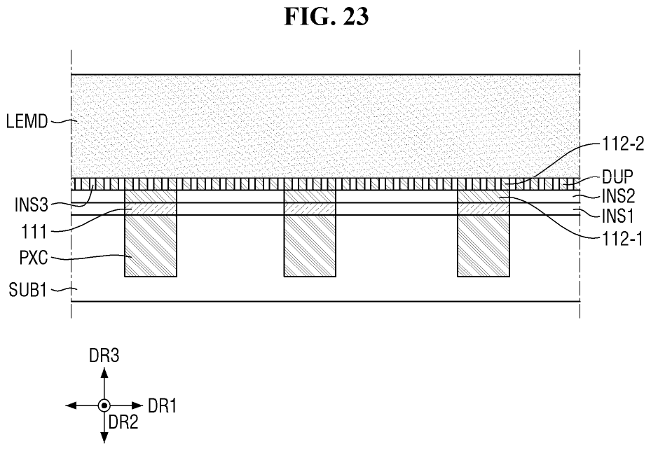

Next, as illustrated in FIGS. 22 and 23, the first connection electrodes 112-1 and the connection electrode patterns 112-2P are bonded to each other and the second substrate SUB2 is removed (S130 of FIG. 15).

More specifically, the first connection electrodes 112-1 of the first substrate SUB1 is brought into contact with the connection electrode patterns 112-2P of the second substrate SUB2. In this case, areas where the light emitting elements LE are to be formed are not defined on the second substrate SUB2, and thus, there is no need to align the connection electrode patterns 112-2P on the first connection electrodes 112-1.

The first connection electrodes 112-1 and the connection electrode patterns 112-2P of the second substrate SUB2 may be melt-bonded to each other at a suitable temperature (e.g., a predetermined temperature) in a state in which they are in contact with each other. Connection electrode patterns 112-2P disposed between the first connection electrodes 112-1 disposed on the upper surfaces of the pixel electrodes 111 of the first substrate SUB1 and the light emitting material layer LEML of the second substrate SUB2 from among the connection electrode patterns 112-2P are defined as second connection electrodes 112-2. The second connection electrodes 112-2 serve as bonding metal layers bonding the pixel electrodes 111 of the first substrate SUB1 and the light emitting material layer LEML of the second substrate SUB2 to each other together with the first connection electrodes 112-1. In one or more embodiments, connection electrode patterns 112-2P that do not overlap the first connection electrodes 112-1 in the third direction DR3 from among the connection electrode patterns 112-2P are defined as dummy electrodes DUP. That is, the connection electrode patterns 112-2P serving as bonding metal layers bonding the pixel electrodes 111 and the light emitting material layer LEML to each other from among the connection electrode patterns 112-2P become the second connection electrodes 112-2, and the other connection electrode patterns 112-2P become the dummy electrodes DUP. A plurality of dummy electrodes DUP are formed not only to be spaced from each other but also to be spaced from the sub-connection electrodes, and thus, do not need to be removed.

Then, the second substrate SUB2 and the buffer layer BF may be removed through a polishing process such as a chemical mechanical polishing (CMP) process and/or an etching process. In addition, the second semiconductor material layer LEMU of the light emitting material layer LEML may be removed through a polishing process such as a CMP process.

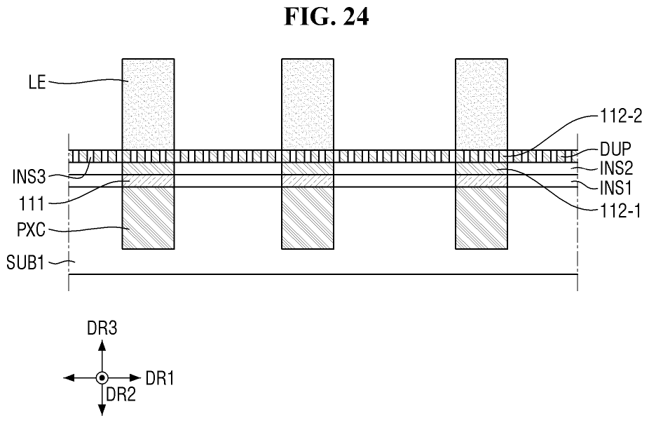

As illustrated in FIG. 24, the light emitting elements LE are formed by etching the light emitting material layer LEML (S140 of FIG. 15).

To this end, a mask pattern is formed on an upper surface of the light emitting material layer LEML. The upper surface of the light emitting material layer LEML may be an upper surface of the first light emitting material layer LEMD exposed by removing the second substrate SUB2, the buffer layer BF, and the second light emitting material layer LEMU. The mask pattern may be disposed in areas where the light emitting elements LE are to be formed. Accordingly, the mask pattern may overlap the pixel electrodes 111 in the third direction DR3. The mask pattern may include a conductive material such as nickel (Ni). A thickness of the mask pattern may be approximately 0.01 to 1 μm.

More specifically, the mask pattern may not be etched by an etching material for etching the light emitting material layer LEML. Accordingly, the light emitting material layer LEML in an area where the mask pattern is disposed may not be etched. Therefore, the light emitting element LE may be formed on the upper surface of each of the pixel electrodes 111. Then, the mask pattern is removed.

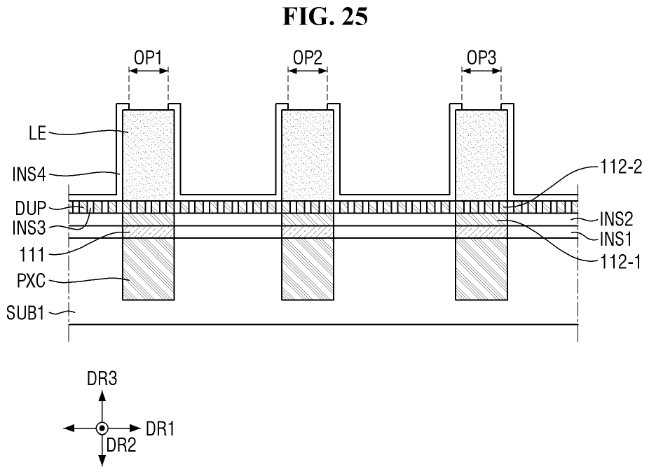

Next, as illustrated in FIGS. 25 to 28, the fourth insulating layer INS4, the common electrode CE, and the first reflective layer RF1 are formed (S150 of FIG. 15).

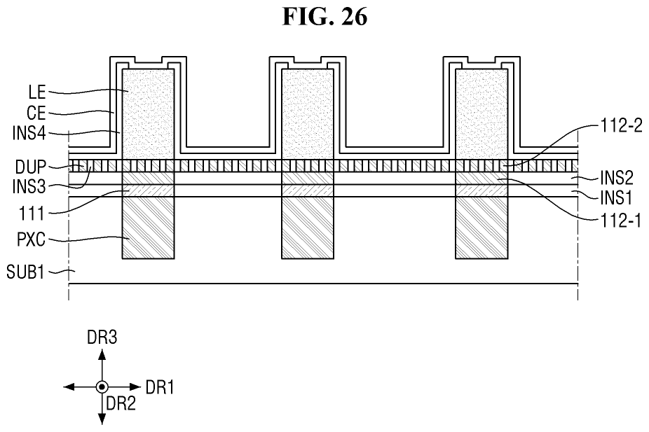

To this end, as illustrated in FIG. 25, the fourth insulating layer INS4 is deposited to cover the entire surface of the first substrate SUB1 on which the light emitting elements LE are disposed. Next, openings OP1, OP2, and OP3 are formed on the light emitting elements LE using photoresist. Accordingly, as illustrated in FIG. 26, the fourth insulating layer INS4 may be deposited on upper surfaces and side surfaces of the light emitting elements LE excluding the openings OP1, OP2 and OP3, upper surfaces of the dummy electrodes DUP, and the third insulating layer INS3 on which the light emitting elements LE are not disposed, and upper areas of the light emitting elements LE may be exposed through the openings OP1, OP2, and OP3.

Next, as illustrated in FIG. 26, the common electrode CE is deposited on the upper surfaces of the light emitting elements LE that are not covered by the fourth insulating layer INS4 and on the fourth insulating layer INS4. The upper surfaces of the light emitting elements LE that are not covered by the fourth insulating layer INS4 are the upper surfaces of the light emitting elements LE exposed by the openings OP1, OP2, and OP3. That is, the light emitting elements LE may be in contact with the common electrode CE through the openings OP1, OP2, and OP3. The common electrode CE may include a transparent conductive oxide (TCO) such as indium tin oxide (ITO) or indium zinc oxide (IZO).

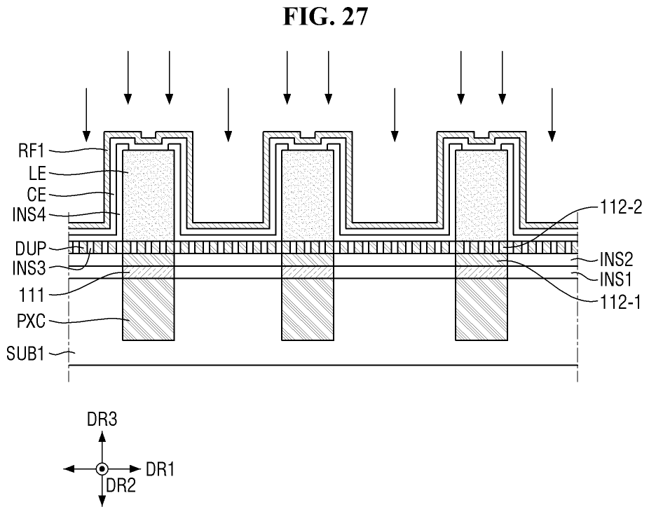

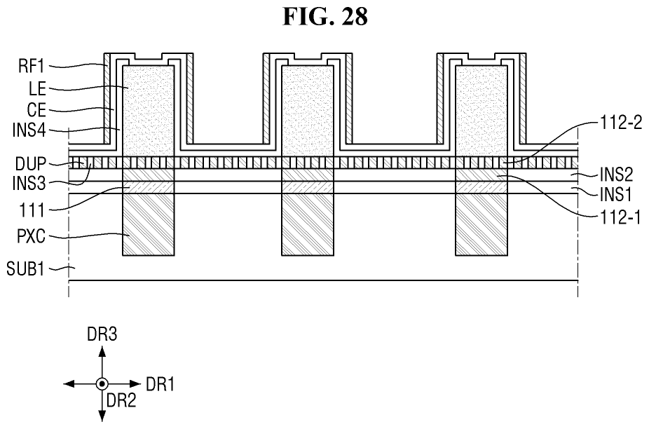

Next, as illustrated in FIG. 27, the first reflective layer RF1 is deposited to cover the common electrode CE. Then, a large voltage difference is formed in the third direction DR3 without a separate mask, and the first reflective layer RF1 is etched using an etching material. In this case, the etching material may etch the first reflective layer RF1 while moving in the third direction DR3, that is, moving from an upper portion to a lower portion, by voltage control. Accordingly, as illustrated in FIG. 28, the first reflective layer RF1 disposed on a horizontal plane defined by the first direction DR1 and the second direction DR2 may be removed, whereas the first reflective layer RF1 disposed on a vertical plane defined by the third direction DR3 may not be removed. Therefore, in each of non-emission areas NEA, the first emission areas EA1, the second emission areas EA2, and the third emission areas EA3, the first reflective layer RF1 disposed on an upper surface of the common electrode CE in each of the light emitting elements LE may be removed. The first reflective layer RF1 disposed on the side surfaces of the light emitting elements LE may not be removed. Accordingly, the first reflective layer RF1 may be disposed on the side surfaces of the light emitting elements LE on the common electrode CE.

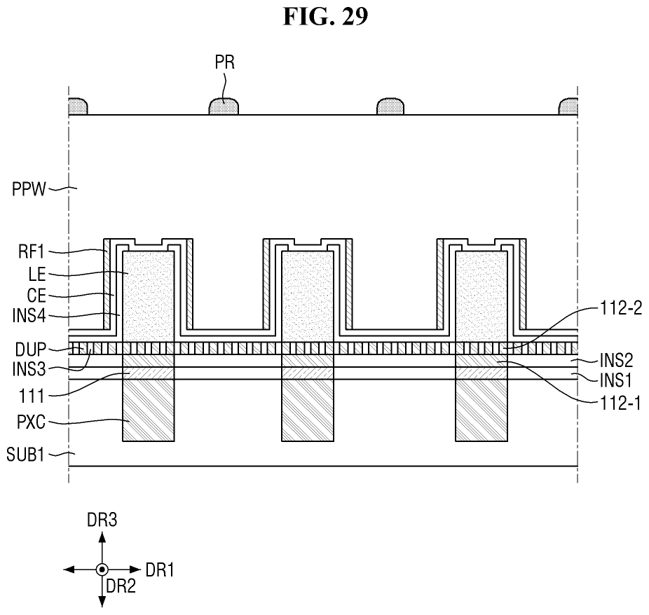

Next, as illustrated in FIGS. 29 to 32, the partition walls PW, the second reflective layer RF2, and the wavelength conversion layers QDL are formed (S160 of FIG. 15).

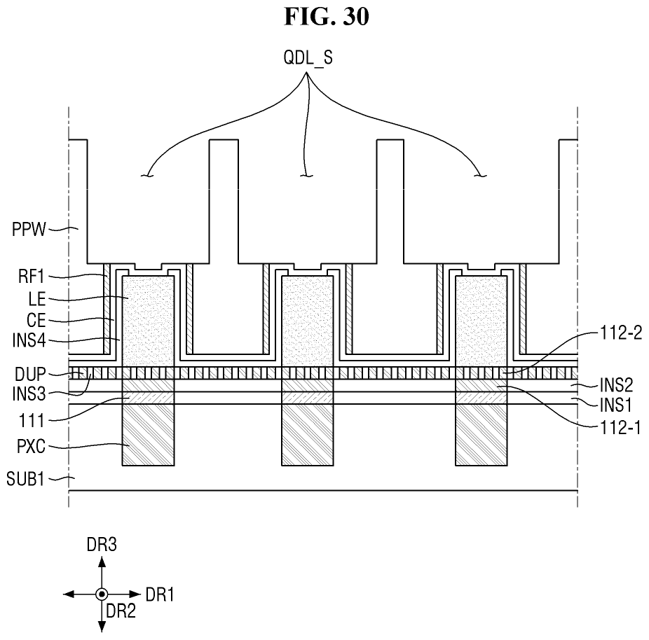

More specifically, as illustrated in FIG. 29, an organic insulating material PPW is applied onto the light emitting elements on which the first reflective layer RF1 is formed, a mask pattern PR is disposed in the non-emission areas, and patterning is performed. Accordingly, as illustrated in FIG. 30, the non-emission areas are not etched, such that the partition walls PW may be formed and spaces QDL-S for the wavelength conversion layers QDL and the light transmission layer TPL may be formed in the emission areas where the mask pattern is not disposed. An upper portion of the common electrode CE is exposed at the bottoms of the spaces QDL-S for the wavelength conversion layers QDL. Thereafter, the mask pattern is removed.

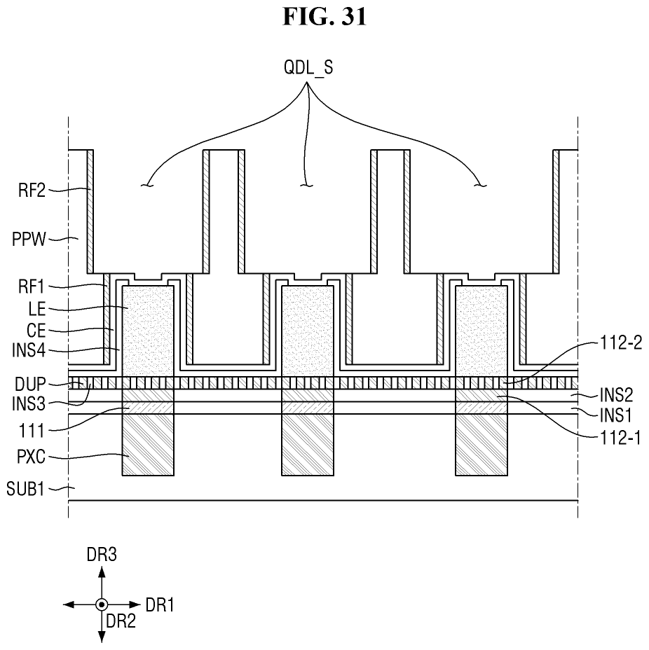

Next, as illustrated in FIG. 31, the second reflective layer RF2 is deposited to cover the first substrate SUB1 on which the partition walls PW and the spaces QDL-S for the wavelength conversion layers are formed. As in a case of forming the first reflective layer RF1, a large voltage difference is formed in the third direction DR3 without a separate mask, and a reflective layer is etched using an etching material. Therefore, in each of the partition walls PW, the first emission areas EA1, the second emission areas EA2, and the third emission areas EA3, the second reflective layer RF2 disposed on the upper surfaces of the light emitting elements LE may be removed. The second reflective layer RF2 disposed on side surfaces of the partition walls PW may not be removed. Accordingly, the second reflective layer RF2 may be disposed on the side surfaces of the partition walls PW in each of the first emission areas EA1, the second emission areas EA2, and the third emission areas EA3.

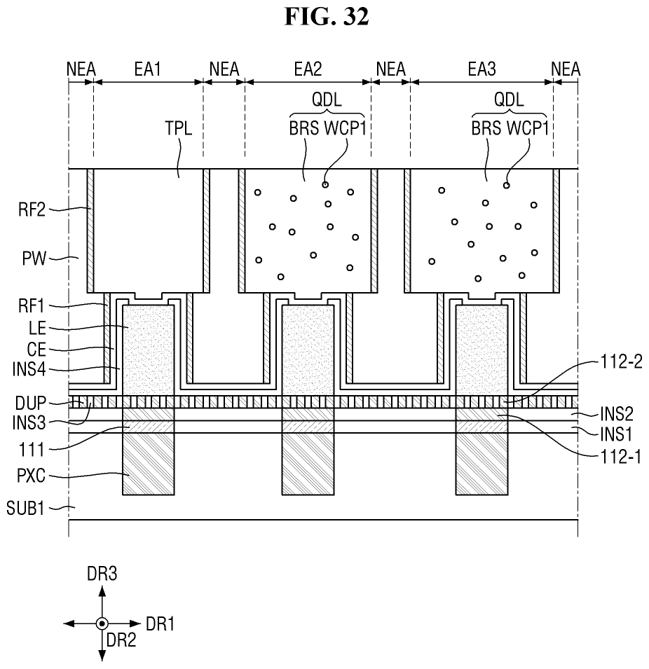

Next, as illustrated in FIG. 32, the wavelength conversion layers QDL and the light transmission layer TPL are formed in the spaces QDL-S for the wavelength conversion layers QDL and the light transmission layer TPL formed between the partition walls PW. The wavelength conversion layers QDL and the light transmission layer TPL may be formed to fill the spaces QDL-S for a plurality of wavelength conversion layers QDL and the light transmission layer TPL. The wavelength conversion layers QDL may be formed by a solution process such as inkjet printing or imprinting of a solution in which first scatterers WCP1 are mixed with the base resin BRS, but are not limited thereto. The wavelength conversion layers QDL may be formed within the spaces QDL-S for the plurality of wavelength conversion layers QDL, respectively, and may be formed to overlap the plurality of emission areas.

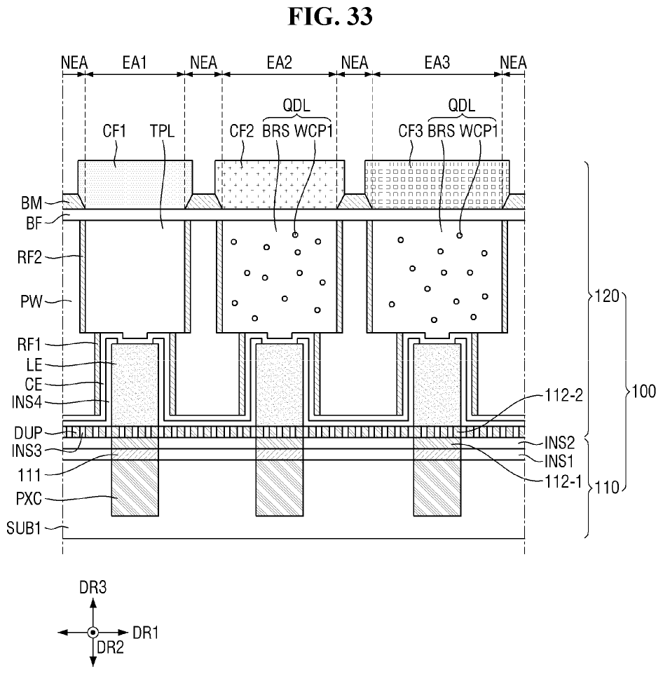

As illustrated in FIG. 33, the plurality of color filters CF1, CF2, and CF3 are formed (S170 of FIG. 15).

In one or more embodiments, the buffer layer BF may be further formed before forming the plurality of color filters CF1, CF2, and CF3.

The buffer layer BF is formed to cover the partition walls PW and the wavelength conversion layers QDL. One surface, for example, an upper surface of the buffer layer BF may be in contact with each of lower surfaces of the plurality of color filters CF1, CF2, CF3 and light blocking members BM. In addition, the other surface, for example, a lower surface, of the buffer layer BF opposite one surface of the buffer layer BF may be in contact with each of upper surfaces of the partition walls PW, and the light transmission layer TPL, and the wavelength conversion layers QDL. The buffer layer BF may include an inorganic insulating material. For example, the buffer layer BF may include silicon oxide (SiOₓ), silicon nitride (SiNₓ), silicon oxynitride (SiOₓN_{y}), aluminum oxide (AlₓO_{y}), aluminum nitride (AlN), or the like, but is not limited thereto. In one or more embodiments, the buffer layer BF may be omitted.

Then, the light blocking members BM are formed on the partition walls PW. The light blocking members BM are formed by applying a light blocking material and patterning the light blocking material. The light blocking members BM are formed to overlap the non-emission areas NEA and to not overlap the emission areas EA1, EA2, and EA3. Next, the color filter CF1 is formed on the wavelength conversion layer QDL partitioned by the light blocking members BM. The color filter CF1 may be formed through a photo process. The color filter CF1 may be formed at a thickness of 1 μm or less, but is not limited thereto. Similarly, other color filters are also formed to overlap respective openings through a patterning process.

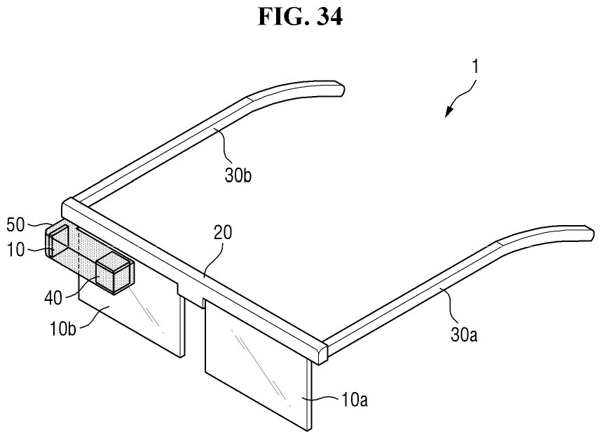

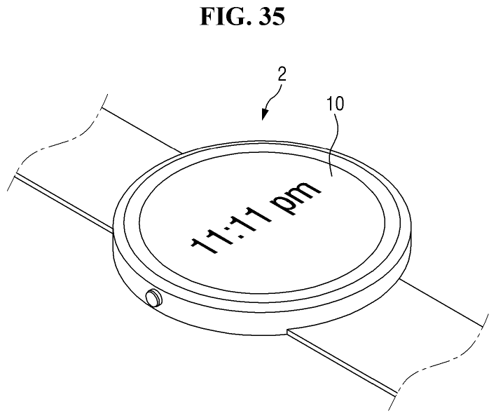

FIG. 34 is a view illustrating a virtual reality device including a display device according to one or more embodiments. In FIG. 34, a virtual reality device 1 to which a display device 10 according to one or more embodiments is applied is shown.

Referring to FIG. 34, the virtual reality device 1 according to one or more embodiments may be a glasses-type device. The virtual reality device 1 according to one or more embodiments may include a display device 10, a left-eye lens 10a, a right-eye lens 10b, a support frame 20, glasses frame legs 30a and 30b, a reflection member 40, and a display device accommodating portion 50.

Although FIG. 34 illustrates the virtual reality device 1 that includes glasses frame legs 30a and 30b, the virtual reality device 1 according to one or more embodiments may be applied to a head mounted display including a head mounting band, which may be mounted on a head, instead of the glasses frame legs 30a and 30b. That is, the virtual reality device 1 according to one or more embodiments is not limited to that shown in FIG. 33, and is applicable to various electronic devices in various forms.

The display device accommodating portion 50 may include a display device 10 and a reflection member 40. The image displayed on the display device 10 may be reflected by the reflection member 40 and provided to a user's right eye through the right-eye lens 10b. For this reason, the user may view a virtual reality image displayed on the display device 10 through the right eye.

Although FIG. 34 illustrates that the display device accommodating portion 50 is disposed at a right end of the support frame 20, the embodiment of the present disclosure is not limited thereto. For example, the display device accommodating portion 50 may be disposed at a left end of the support frame 20, and in this case, the image displayed on the display device 10 may be reflected by the reflection member 40 and provided to the user's left eye through the left-eye lens 10a. For this reason, the user may view the virtual reality image displayed on the display device 10 through the left eye. Alternatively, the display device accommodating portion 50 may be disposed at both the left end and the right end of the support frame 20, and in this case, the user may view the virtual reality image displayed on the display device 10 through both the left eye and the right eye.

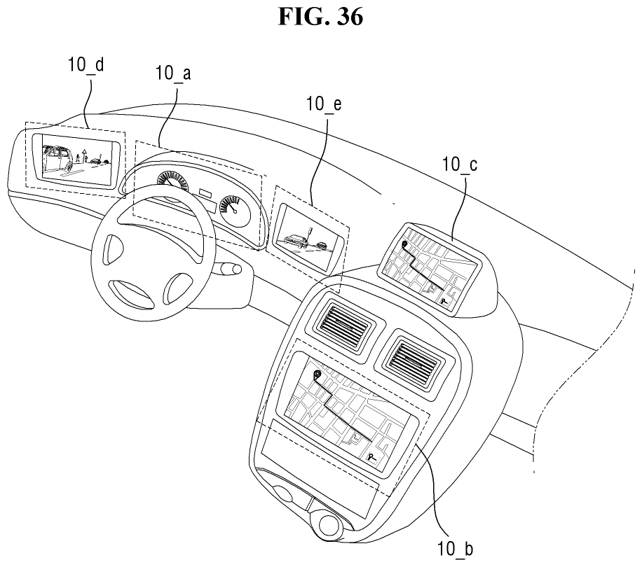

FIG. 35 is a view illustrating a smart device including a display device according to one or more embodiments.

Referring to FIG. 35, a display device 10 according to one or more embodiments may be applied to a smart watch 2, which is one of the smart device.

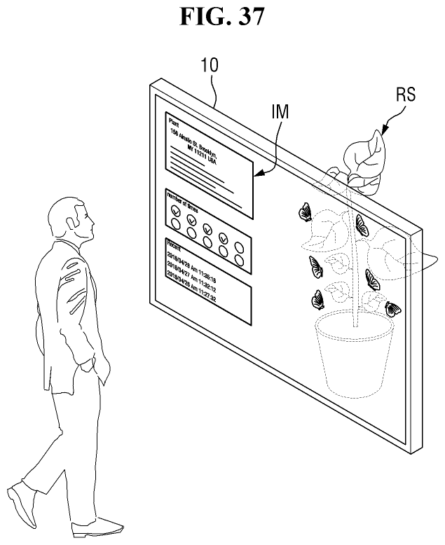

FIG. 36 is a view illustrating a vehicle dashboard and a center fascia including a display device according to one or more embodiments. A vehicle to which display devices 10 according to one or more embodiments are applied is shown in FIG. 36.

Referring to FIG. 36, the display devices 10_a, 10_b and 10_c according to one or more embodiments may be applied to a dashboard of the vehicle, applied to a center fascia of the vehicle, or applied to a center information display (CID) disposed on the dashboard of the vehicle. Alternatively, the display devices 10_a, 10_b and 10_c may be used as a display device. In addition, the display devices 10_d and 10_e according to one or more embodiments may be applied to a room mirror display that replaces a side mirror of the vehicle.

FIG. 37 is a view illustrating a transparent display device including a display device according to one or more embodiments.

Referring to FIG. 37, a display device 10 according to one or more embodiments may be applied to the transparent display device. The transparent display device may display an image IM and at the same time transmit light. Therefore, a user located on a front surface of the transparent display device may not only view the image IM displayed on the display device 10 but also view an object RS or background located on a rear surface of the transparent display device. When the display device 10 is applied to the transparent display device, the first substrate SUB1 of the display device 10 shown in FIG. 5 may include a light transmitting portion capable of transmitting light or may be formed of a material capable of transmitting light.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A display device comprising:
a substrate comprising pixel circuit units;
a plurality of pixel electrodes and first connection electrodes located thereon, the plurality of pixel electrodes being on the pixel circuit units of the substrate; and
a plurality of light emitting elements on the plurality of pixel electrodes and comprising second connection electrodes bonded to the first connection electrodes,
wherein each of the second connection electrodes comprises a plurality of sub-connection electrodes that are spaced from each other.

2. The display device of claim 1, further comprising:
a first insulating layer on the substrate at locations where the first connection electrodes are not located; and
a plurality of dummy electrodes on the first insulating layer and not overlapping the first connection electrode.

3. The display device of claim 2, further comprising a second insulating layer between the plurality of dummy electrodes.

4. The display device of claim 3, wherein at least one of the plurality of sub-connection electrodes protrudes outside the first connection electrode, and
wherein the at least one sub-connection electrode protruding outside the first connection electrode from among the plurality of sub-connection electrodes is on the first insulating layer.

5. The display device of claim 3, further comprising a third insulating layer on upper surfaces and side surfaces of the plurality of light emitting elements, upper surfaces of the plurality of dummy electrodes, and an upper surface of the second insulating layer,
wherein the third insulating layer includes openings on upper surface of the plurality of light emitting elements.

6. The display device of claim 2, wherein the plurality of sub-connection electrodes and the plurality of dummy electrodes are spaced from each other by a first interval in at least a first direction, and
wherein the dummy electrode neighboring to the sub-connection electrode is spaced from the sub-connection electrode by the first distance in at least the first direction.

7. The display device of claim 1, wherein each of the plurality of sub-connection electrodes has a first width in a first direction,
wherein the first connection electrode has a second width in the first direction, and
wherein the first width is smaller than the second width.

8. The display device of claim 7, wherein a sum of the first widths of the plurality of sub-connection electrodes arranged in the first direction in the second connection electrode is smaller than the second width of the first connection electrode.

9. The display device of claim 5, further comprising a common electrode on the third insulating layer and electrically connected to the plurality of light emitting elements through the openings.

10. The display device of claim 9, further comprising:
partition walls between the plurality of light emitting elements, the partition walls defining spaces in emission areas on the respective light emitting elements;
wavelength conversion layers located in the spaces;
a first reflective layer on side surfaces of the plurality of light emitting elements; and
a second reflective layer on side surfaces of the wavelength conversion layers.

11. The display device of claim 10, wherein a length of the wavelength conversion layer in a direction perpendicular to a thickness direction of the substrate is greater than a length of the light emitting element in the direction perpendicular to the thickness direction of the substrate, and
wherein the display device further comprises a third reflective layer at bottom portions of the wavelength conversion layers that do not overlap the light emitting elements.

12. The display device of claim 10, further comprising:
light blocking members on the partition walls; and
color filters on the wavelength conversion layers.

13. A method for manufacturing a display device, comprising:
forming first connection electrodes and a first insulating layer on pixel electrodes formed on pixel circuit units of a first substrate;
forming a plurality of connection electrode patterns and a second insulating layer over an entire surface of a light emitting material layer of a second substrate;
bonding the first connection electrodes and the connection electrode patterns to each other and separating the second substrate; and
forming light emitting elements by etching the light emitting material layer,
wherein the plurality of connection electrode patterns include a plurality of sub-connection electrodes bonded to the first connection electrode and a plurality of dummy electrodes that do not overlap the first connection electrode.

14. The method for manufacturing a display device of claim 13, wherein the plurality of sub-connection electrodes bonded to the first connection electrode are defined as second connection electrodes and connect the light emitting element and the pixel electrode to each other.

15. The method for manufacturing a display device of claim 13, wherein the plurality of connection electrode patterns are spaced from each other by a first distance in at least a first direction.

16. The method for manufacturing a display device of claim 13, wherein each of the plurality of sub-connection electrodes has a first width in a first direction,
wherein the first connection electrode has a second width in the first direction, and
wherein the first width is smaller than the second width.

17. The method for manufacturing a display device of claim 13, further comprising, after the forming of the light emitting elements,
forming a third insulating layer on upper surfaces and side surfaces of the light emitting elements, upper surfaces of the plurality of dummy electrodes, and an upper surface of the second insulating layer;
forming openings exposing portions of the upper surfaces of the light emitting elements by etching the third insulating layer on the upper surfaces of the light emitting elements; and
forming a common electrode on the openings and the third insulating layer.

18. The method for manufacturing a display device of claim 17, further comprising removing a reflective layer in a first direction and a second direction by an etching material and forming a first reflective layer overlapping the side surfaces of the light emitting elements by depositing the reflective layer on the common electrode and then forming a large voltage difference in a third direction.

19. The method for manufacturing a display device of claim 18, further comprising:
forming spaces for wavelength conversion layers and partition walls by applying an organic insulating material layer to the light emitting elements so as to cover the light emitting elements and etching the organic insulating material layer on the light emitting elements; and
forming the wavelength conversion layers in the spaces.

20. The method for manufacturing a display device of claim 19, further comprising, before the forming of the wavelength conversion layers,
removing a reflective layer in the first direction and the second direction by an etching material and forming a second reflective layer overlapping side surfaces of the spaces by depositing the reflective layer on the partition walls and the spaces and then forming a large voltage difference in the third direction.
